(19) United States
(12) Patent Application Publication
(10) Pub. No.: US 2024/0254360 A1
(43) Pub. Date: Aug. 1, 2024

(54) RESIN COMPOSITION, PREPREG, RESIN SHEET, LAMINATE, METAL FOIL-CLAD LAMINATE, AND PRINTED WIRING BOARD

(71) Applicant: MITSUBISHI GAS CHEMICAL COMPANY, INC., Tokyo (JP)

(72) Inventors: Tatsuro TAKAMURA, Tokyo (JP); Naoki KASHIMA, Tokyo (JP); Sayaka ITO, Tokyo (JP); Narihiro URAHAMA, Tokyo (JP); Kazuki SUNAKAWA, Tokyo (JP); Tetsuro MIYAHIRA, Tokyo (JP); Takaaki OGASHIWA, Tokyo (JP)

(73) Assignee: MITSUBISHI GAS CHEMICAL COMPANY, INC., Tokyo (JP)

(21) Appl. No.: 18/561,932

(22) PCT Filed: May 23, 2022
(86) PCT No.: PCT/JP2022/021040

§ 371 Date: Nov. 17, 2023

(30) Foreign Application Priority Data
May 28, 2021 (JP) 2021-090391
Mar. 23, 2022 (JP) 2022-046580

(51) Int. Cl. C09D 161/28; C08G 73/10; C08J 5/18; C08J 5/24; C08K 3/22; C08K 9/02; C08K 9/04; C08L 61/28

(52) U.S. Cl. CPC C09D 161/28; C08G 73/1035; C08J 5/18; C08J 5/246; C08K 3/22; C08K 9/02; C08K 9/04; C08L 61/28; C08J 2361/28; C08K 2003/2237; C08L 2203/206

(57) ABSTRACT

A resin composition is provided having a high permittivity and a low dissipation factor, and having excellent moisture absorption and heat resistance, a high glass transition temperature, a low coefficient of thermal expansion, and good coatability and appearance, and used for producing an insulation layer of a printed wiring board; and a prepreg, a resin sheet, a laminate, a metal foil-clad laminate, and a printed wiring board. The resin composition contains: (A) a cyanate ester compound, (B) a maleimide compound, and (C) a surface-coated titanium oxide, wherein a content of the cyanate ester compound (A) is 1 to 65 parts by mass, based on 100 parts by mass of a total resin solid content in the resin composition, and a content of the maleimide compound (B) is 15 to 85 parts by mass, based on 100 parts by mass of a total resin solid content in the resin composition.

### TECHNICAL FIELD

The present invention relates to a resin composition, a prepreg, a resin sheet, a laminate, a metal foil-clad laminate, and a printed wiring board.

### BACKGROUND ART

In recent years, signal bands for information and telecommunication device such as PHS and mobile phones, and CPU clock time of computers have reached the GHz band, and thus the frequency has been higher. A dielectric loss of an electrical signal is proportionate to the product of a square root of a relative permittivity and a dissipation factor of an insulation layer forming a circuit, and a frequency of the electrical signal. For this reason, the higher a frequency of a signal used, the greater a dielectric loss becomes. An increase in the dielectric loss dampens an electrical signal to undermine the reliability of the signal. It is necessary for preventing this to select a material having low permittivity and dissipation factor for an insulation layer.

On the other hand, for an insulation layer of a high frequency circuit, there are demands for formation of a delay circuit, impedance matching of a wiring board in a low impedance circuit, a finer wiring pattern, and a circuit more complex with a substrate having a built-in capacitor, and there is a case where an insulation layer with a higher permittivity is required. For this reason, electronic components in which an insulation layer having a high permittivity and a low dissipation factor is used have been proposed (e.g., Patent Document 1). An insulation layer having a high permittivity and a low dissipation factor is formed by dispersing a filler such as a ceramic powder and an insulated metal powder in a resin.

For the insulation layer, for example, a resin composition that includes a cyanate ester compound in combination with a maleimide compound is used due to excellent heat resistance, electrical properties and the other properties.

### CITATION LIST

### Patent Document

Patent Document 1: Japanese Patent Laid-Open No. 2000-91717

### SUMMARY OF INVENTION

### Technical Problem

For increasing the relative permittivity of an insulation layer, a filler having a high relative permittivity is required to be blended; however a dissipation factor also simultaneously increases, thereby posing the problem of a higher transmission loss of a higher frequency signal.

The filler used for producing the insulation layer having a high permittivity and a low dissipation factor typically has a high specific gravity. For this reason, the filler is poorly dispersed and unevenly distributed in a resin composition, thereby posing the problem of the poor coatability and therefore an aggravated appearance of a molded article.

Additionally, when an insulation layer has low moisture absorption and heat resistance, water boils inside during reflow operation, thereby forming voids. For this reason, in the field of electronic materials where extremely high reliability is required, the insulation layer is demanded to have excellent moisture absorption and heat resistance.

Further, an insulation layer with a low glass transition temperature (Tg) and a high coefficient of thermal expansion causes warpage and interfacial delamination when producing a laminate. For this reason, it is also important for the resin and the filler used for a printed wiring board and the like to have a high glass transition temperature and a low coefficient of thermal expansion.

The present invention has been made to solve the problem described above and has aimed to provide a resin composition having a high permittivity and a low dissipation factor, and having excellent moisture absorption and heat resistance, a high glass transition temperature, and a low coefficient of thermal expansion, and also a good coatability and appearance, and suitably used for producing an insulation layer of a printed wiring board; and a prepreg, a resin sheet, a laminate, a metal foil-clad laminate, and a printed wiring board obtainable by using the resin composition.

### Solution to Problem

The present inventors have conducted extensive studies to solve the above problems posed by the conventional technology, and have found that a specific resin composition can solve the above problems, whereby the present invention has been accomplished.

Specifically, the present invention is as follows.

[1] A resin composition containing: (A) a cyanate ester compound; (B) a maleimide compound; and (C) a surface-coated titanium oxide; wherein a content of the cyanate ester compound (A) is 1 to 65 parts by mass, based on 100 parts by mass of a total resin solid content in the resin composition, and a content of the maleimide compound (B) is 15 to 85 parts by mass, based on 100 parts by mass of the total resin solid content in the resin composition.

[2] The resin composition according to [1], wherein the cyanate ester compound (A) contains one or more selected from the group consisting of phenol novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallyl bisphenol A-type cyanate ester compounds, bisphenol E-type cyanate ester compounds, bisphenol F-type cyanate ester compounds, and biphenyl aralkyl-type cyanate ester compounds, and prepolymers or polymers of these cyanate ester compounds.

[3] The resin composition according to [1] or [2], wherein the maleimide compound (B) contains one or more selected from the group consisting of bis(4-maleimidephenyl)methane, 2,2-bis(4-(4-maleimidephenoxy)-phenyl)propane, bis(3-ethyl-5-methyl-4-maleimidephenyl)methane, maleimide compounds represented by the following formula (2) and maleimide compounds represented by the following formula (3):

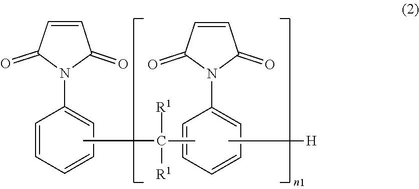

wherein R¹ each independently represents a hydrogen atom or a methyl group, and n1 is an integer of 1 to 10,

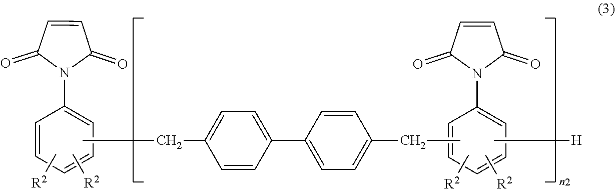

wherein R² each independently represents a hydrogen atom, an alkyl group having 1 to 5 carbon atoms, or a phenyl group, n2 is an average value and represents 1<n2≤5.

[4] The resin composition according to any of [1] to [3], further containing one or more thermosetting resins or compounds selected from the group consisting of epoxy compounds, phenolic compounds, modified polyphenylene ether compounds, alkenyl-substituted nadiimide compounds, oxetane resins, benzoxazine compounds, and compounds having a polymerizable unsaturated group.

[5] The resin composition according to any of [1] to [4], wherein the surface-coated titanium oxide (C) has an organic layer and/or an inorganic oxide layer on the surface of a titanium oxide particle.

[6] The resin composition according to [5], wherein a total amount of the organic layer and the inorganic oxide layer is 0.1 to 10 mass %, based on 100 mass % of the surface-coated titanium oxide (C).

[7] The resin composition according to [5] or [6], wherein the inorganic oxide layer is one or more selected from the group consisting of a layer containing silica, a layer containing zirconia, and a layer containing alumina.

[8] The resin composition according to [7], wherein the surface-coated titanium oxide (C) further has the organic layer on the surface of the inorganic oxide layer.

[9] The resin composition according to any of [1] to [8], wherein a content of the surface-coated titanium oxide (C) is 50 to 500 parts by mass, based on 100 parts by mass of a total resin solid content in the resin composition.

[10] The resin composition according to any of [1] to [9], further containing a filler different from the surface-coated titanium oxide (C).

[11] The resin composition according to [10], wherein the filler contains one or more selected from the group consisting of silica, alumina, barium titanate, strontium titanate, calcium titanate, aluminum nitride, boron nitride, boehmite, aluminum hydroxide, zinc molybdate, silicone rubber powder, and silicone composite powder.

[12] The resin composition according to [10] or [11], wherein a content of the filler is 50 to 300 parts by mass, based on 100 parts by mass of a total resin solid content in the resin composition.

[13] The resin composition according to [4], wherein the epoxy compound contains one or more selected from the group consisting of biphenyl aralkyl-type epoxy resins, naphthalene-type epoxy resins, and naphthylene ether-type epoxy resins.

[14] The resin composition according to any of [1] to [13], for use in a printed wiring board.

[15] A prepreg containing a base material, and the resin composition according to any of [1] to [14] penetrating or coating the base material.

[16] A resin sheet containing the resin composition according to any of [1] to [14].

[17] A laminate containing one or more selected from the group consisting of the prepreg according to [15] and the resin sheet according to [16].

[18] A metal foil-clad laminate containing the laminate according to [17] and a metal foil disposed on one side or each of both sides of the laminate.

[19] A printed wiring board, containing an insulation layer, and a conductor layer disposed on one side or each of both sides of the insulation layer, wherein the insulation layer contains a cured product of the resin composition according to any of [1] to [14].

### Advantageous Effects of Invention

The resin composition of the present invention can accordingly provide a resin composition having a high permittivity and a low dissipation factor, and having excellent moisture absorption and heat resistance, a high glass transition temperature, a low coefficient of thermal expansion, and also a good coatability and appearance, and suitably used for producing an insulation layer of a printed wiring board; and a prepreg, a resin sheet, a laminate, a metal foil-clad laminate, and a printed wiring board obtainable by using the resin composition.

### DESCRIPTION OF EMBODIMENTS

Hereinafter, embodiments to carry out the present invention (hereinafter, referred to as the “present embodiment”) will be described in more detail. The following present embodiments are examples to illustrate the present invention and do not intend to limit the present invention to the contents below. The present invention can be carried out with appropriate modifications within the scope of the spirit thereof.

In the present embodiments, the “resin solid content” or the “resin solid content in the resin composition” refers to the resin components of the resin composition, excluding surface-coated titanium oxide (C), the filler, additives (a silane coupling agent, a wetting and dispersing agent, a curing accelerator, and other components) and a solvent, and “100 parts by mass of the total resin solid content” refers that the total amount of the resin components of the resin composition, excluding surface-coated titanium oxide (C), the filler, additives (a silane coupling agent, a wetting and dispersing agent, a curing accelerator, and other components) and a solvent, is regarded as 100 parts by mass, unless otherwise noticed.

### [Resin Composition]

The resin composition of the present embodiment contains: (A) a cyanate ester compound, (B) a maleimide compound, and (C) a surface-coated titanium oxide, wherein a content of cyanate ester compound (A) is 1 to 65 parts by mass based on 100 parts by mass of the total resin solid content in the resin composition, and a content of maleimide compound (B) is 15 to 85 parts by mass based on 100 parts by mass of the total resin solid content in the resin composition.

Since the resin composition of the present embodiment contains (A) a cyanate ester compound, (B) a maleimide compound, and (C) a surface-coated titanium oxide wherein cyanate ester compound (A) and maleimide compound (B) are contained in the respective specific amounts, an insulation layer of a printed wiring board having a high permittivity and a low dissipation factor, and having excellent moisture absorption and heat resistance, a high glass transition temperature, a low coefficient of thermal expansion, and also a good coatability and appearance can be suitably obtained. The reason is not clear but the present inventors infer as follows.

Specifically, the resin composition that includes the cyanate ester compound in combination with the maleimide compound has extremely excellent heat resistance and electrical properties. However, when titanium oxide whose surface is not coated (hereinafter, referred to as the “surface uncoated titanium oxide”) is incorporated into the resin composition that includes the cyanate ester compound in combination with the maleimide compound, the surface uncoated titanium oxide forms a complex with the cyanate ester compound and/or maleimide compound, thereby accelerating the hydrolysis of the cyanate ester compound and/or maleimide compound, whereby the insulation layer to be obtained easily absorbs moisture in the atmosphere. For this reason, in the cured product to be obtained, the absorbed moisture boils during reflow operation, thereby forming voids in the insulation layer. Additionally, in the case where a surface-coated titanium oxide instead of the surface uncoated titanium oxide is used, voids may be formed in the insulation layer as in the surface uncoated titanium oxide. Further, the resin composition including the cyanate ester compound and the maleimide compound with the surface-coated titanium oxide may pose problems of an extended curing time, deteriorated coatability, and an aggravated appearance.

On the other hand, when the cyanate ester compound and the maleimide compound are blended in the respective specific amounts with the surface-coated titanium oxide in the resin composition, the insulation layer having excellent moisture absorption and heat resistance can be obtained. For this reason, voids are less likely formed in the insulation layer even during reflow operation. From this reason, in the resin compositions such as a resin varnish, high dispersibility of the surface-coated titanium oxide can be retained, thereby less likely causing uneven distribution and aggregation while having a high permittivity and a low dissipation factor. For this reason, the surface-coated titanium oxide has excellent dispersibility in the cyanate ester compound and the maleimide compound, and the resin composition thus has excellent coatability, whereby a molded article having a good appearance can be obtained. Thus, it is inferred that the resin composition according to the present embodiment can efficiently form a dielectric channel in the insulation layer while having excellent moisture absorption and heat resistance, and that the insulation layer to be obtained thus has a high permittivity and a low dissipation factor, and moreover a low coefficient of thermal expansion due to the efficient formation of a thermal path, and further a high glass transition temperature, and also has a good coatability and appearance. However, the mechanism is not limited to this.

### <Cyanate Ester Compound (A)>

The resin composition of the present embodiment contains cyanate ester compound (A).

For cyanate ester compound (A), a known compound can be appropriately used as long as the compound has two or more cyanate groups directly bonding an aromatic ring in the molecule (also referred to as “cyanate ester group”, or “cyanate group”). Those for cyanate ester compound (A) can be used singly, or two or more thereof can also be used in combination.

Examples of such a cyanate ester compound include phenol novolac-type cyanate ester compounds, cresol novolac-type cyanate ester compounds, naphthalene ring-containing novolac-type cyanate ester compounds, allyl group-containing novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallyl bisphenol A-type cyanate ester compounds, bisphenol E-type cyanate ester compounds, bisphenol F-type cyanate ester compounds, biphenyl aralkyl-type cyanate ester compounds, bis(3,3-dimethyl-4-cyanatephenyl)methane, 1,3-dicyanatebenzene, 1,4-dicyanatebenzene, 1,3,5-tricyanatebenzene, 1,3-dicyanatenaphthalene, 1,4-dicyanatenaphthalene, 1,6-dicyanatenaphthalene, 1,8-dicyanatenaphthalene, 2,6-dicyanatenaphthalene, 2,7-dicyanatenaphthalene, 1,3,6-tricyanatenaphthalene, 4,4′-dicyanatebiphenyl, bis(4-cyanatephenyl)ether, bis(4-cyanatephenyl)thioether, and bis(4-cyanatephenyl)sulfone. These cyanate ester compounds can be made into prepolymers or polymers of cyanate ester compounds.

Of these, in view of being more compatible with maleimide compound (B), well dispersing surface-coated titanium oxide (C), and obtaining the resin composition having more favorable thermal characteristics (low coefficient of thermal expansion, moisture absorption and heat resistance, and high glass transition temperature) and more favorable dielectric characteristics (high permittivity and low dissipation factor) during curing, and further obtaining the insulation layer having a suitable surface hardness, cyanate ester compound (A) preferably contains one or more selected from the group consisting of phenol novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallyl bisphenol A-type cyanate ester compounds, bisphenol E-type cyanate ester compounds, bisphenol F-type cyanate ester compounds, and biphenyl aralkyl-type cyanate ester compounds, and prepolymers or polymers of these cyanate ester compounds, and more preferably one or more selected from the group consisting of naphthol aralkyl-type cyanate ester compounds and bisphenol A-type cyanate ester compounds.

For a naphthol aralkyl-type cyanate ester compound, compounds represented by a formula (1) is more preferable.

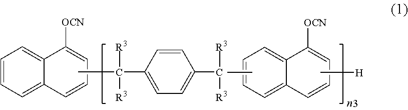

In the formula (1), R³ each independently represents a hydrogen atom or a methyl group, and preferably a hydrogen atom. In the formula (1), n3 is an integer of 1 or more, and is preferably an integer of 1 to 20, and more preferably an integer of 1 to 10.

For the bisphenol A-type cyanate ester compound, one or more selected from the group consisting of 2,2-bis(4-cyanatephenyl)propane and prepolymers of 2,2-bis(4-cyanatephenyl)propane can be used.

Such a bisphenol A-type cyanate ester compound can be a commercial product, and examples include Primaset (registered trademark) BADCy (product name, Lonza K.K., 2,2-bis(4-cyanatephenyl)propane, cyanate ester group equivalent: 139 g/eq.), and CA210 (product name, Mitsubishi Gas Chemical Company, Inc., a prepolymer of 2,2-bis(4-cyanatephenyl)propane, cyanate ester group equivalent: 139 g/eq.).

These cyanate ester compounds can be produced in accordance with a known method. Examples of the specific production method include a method described in Japanese Patent Laid-Open No. 2017-195334 (particularly, paragraphs from 0052 to 0057).

The content of cyanate ester compound (A) is 1 to 65 parts by mass, preferably 2 to 60 parts by mass, more preferably 3 to 55 parts by mass, further preferably 4 to 50 parts by mass, furthermore preferably 5 to 45 parts by mass, and further preferably 6 to 40 parts by mass, based on 100 parts by mass of the total resin solid content in the resin composition. When the content of cyanate ester compound (A) is within the above range, the resin composition can be obtained that includes maleimide compound (B) even more compatible therewith to even more disperse surface-coated titanium oxide (C), and has even more favorable thermal characteristics during curing (low coefficient of thermal expansion, moisture absorption and heat resistance, and high glass transition temperature) and more favorable dielectric characteristics (high permittivity and low dissipation factor), and furthermore, the insulation layer having a more suitable surface hardness tends to be obtained.

### <Maleimide Compound (B)>

The resin composition of the present embodiment contains maleimide compound (B).

For the maleimide compound (B), a known compound can be appropriately used as long as the compound has one or more maleimide groups in a molecule, and the kind thereof is not particularly limited. The number of maleimide groups in a molecule in the maleimide compound (B) is one or more, and preferably two or more. The maleimide compounds (B) can be used singly, or two or more thereof can also be used in combination.

Examples of the maleimide compound (B) include N-phenylmaleimide, N-hydroxyphenylmaleimide, bis(4-maleimidephenyl)methane, 2,2-bis(4-(4-maleimidephenoxy)-phenyl)propane, bis(3,5-dimethyl-4-maleimidephenyl)methane, bis(3-ethyl-5-methyl-4-maleimidephenyl)methane, bis(3,5-diethyl-4-maleimidephenyl)methane, maleimide compounds represented by a formula (2), and maleimide compounds represented by a formula (3), and prepolymers of these maleimide compounds, and prepolymers of the above maleimide compound and an amine compound.

Of these, in view of the much hither compatibility with cyanate ester compound (A) to well disperse surface-coated titanium oxide (C), and obtaining the resin composition having more favorable thermal characteristics during curing (low coefficient of thermal expansion, moisture absorption and heat resistance, and high glass transition temperature) and more favorable dielectric characteristics (high permittivity and low dissipation factor), and further obtaining the insulation layer having a suitable surface hardness, maleimide compound (B) preferably contains one or more selected from the group consisting of bis(4-maleimidephenyl)methane, 2,2-bis(4-(4-maleimidephenoxy)-phenyl)propane, bis(3-ethyl-5-methyl-4-maleimidephenyl)methane, maleimide compounds represented by the formula (2), and maleimide compounds represented by the formula (3), and more preferably contains one or more selected from the group consisting of 2,2-bis(4-(4-maleimidephenoxy)-phenyl)propane, maleimide compounds represented by the formula (2), and maleimide compounds represented by the formula (3).

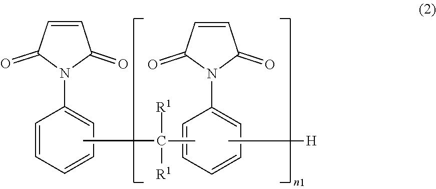

In the formula (2), R¹ each independently represents a hydrogen atom or a methyl group, and n1 is an integer of 1 to 10.

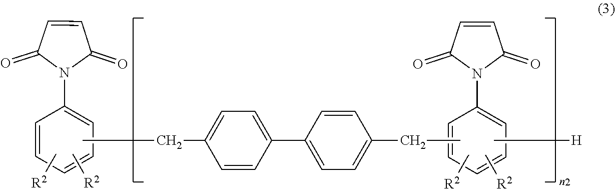

In the formula (3), R² each independently represents a hydrogen atom, an alkyl group having 1 to 5 carbon atoms, or a phenyl group, n2 is an average value and represents 1<n2≤5.

The content of maleimide compound (B) is 15 to 85 parts by mass, preferably 20 to 80 parts by mass, and more preferably 25 to 75 parts by mass, based on 100 parts by mass of the total resin solid content in the resin composition. For the upper limit value, the content of maleimide compound (B) can be 70 parts by mass or less, 65 parts by mass or less, and 60 parts by mass or less. When the content of maleimide compound (B) is within the above range, the resin composition can be obtained that includes maleimide compound (B) even more compatible with cyanate ester compound (A) to even more disperse surface-coated titanium oxide (C), and has even more favorable thermal characteristics during curing (low coefficient of thermal expansion, moisture absorption and heat resistance, and high glass transition temperature) and more favorable dielectric characteristics (high permittivity and low dissipation factor), and furthermore, the insulation layer having a more suitable surface hardness tends to be obtained.

Maleimide compound (B) can be a commercial product, or a product produced by a known method can also be used. Examples of the commercial products of the maleimide compound include BMI-70, BMI-80 and BMI-1000P (these are all product names, K.I Chemical Industry Co., Ltd.); BMI-3000, BMI-4000, BMI-5100, BMI-7000, and BMI-2300 (the maleimide compounds represented by the above formula (2), wherein R¹ is all hydrogen atoms, and n1 is an integer of 1 to 5) (these are all product names, DAIWA KASEI INDUSTRY CO., LTD.); and MIR-3000-70MT (product name, the maleimide compound represented by the above formula (3), wherein R² is all hydrogen atoms, and n2 is an average value and represents 1<n2≤5, Nippon Kayaku Co., Ltd.).

### <Surface-Coated Titanium Oxide (C)>

The resin composition of the present embodiment contains surface-coated titanium oxide (C).

Surface-coated titanium oxide (C) is not particularly limited as long as titanium oxide particles as the core of surface-coated titanium oxide (C) (hereinafter, simply referred to as the “titanium oxide particles” or “core particles”) have an organic layer and/or an inorganic oxide layer on the surface thereon. Surface-coated titanium oxides can be used singly for surface-coated titanium oxide (C), or two or more surface-coated titanium oxides with different particle sizes or surface conditions can also be used in combination.

The median particle size (D50) of surface-coated titanium oxide (C) is preferably 0.1 to 5 μm, and more preferably 0.15 to 1 μm, in view of the dispersibility. Herein, the median particle size (D50) means the value at which a cumulative volume from smaller particles reaches 50% of the entire volume when a particle size distribution of a predetermined amount of a powder fed in a dispersion medium is measured using a laser diffraction scattering type particle size distribution analyzer. The median particle size (D50) can be calculated by measuring particle size distribution by a laser diffraction scattering method, but a specific measurement method can be referred to examples.

The shape of surface-coated titanium oxide (C) is not particularly limited, and examples include scale-like shapes, spherical shapes, plate-like shapes, and amorphous shapes. The shape of surface-coated titanium oxide (C) is preferably spherical and/or amorphous shapes in view of allowing cyanate ester compound (A) and maleimide compound (B) to be more compatible, and obtaining the resin composition having more favorable thermal characteristics during curing (low coefficient of thermal expansion, moisture absorption and heat resistance, and high glass transition temperature) and more favorable dielectric characteristics (high permittivity and low dissipation factor), and further obtaining the insulation layer having a further suitable surface hardness. Herein, the amorphous shape means that the shape of primary particles observed using an electron microscope such as a scanning electron microscope (SEM) is undefined and has many irregular corners and faces. Amorphous surface-coated titanium oxide (C) can be typically obtained by coating the surface with titanium oxide which was crushed and pulverized to be amorphous.

The relative permittivity of surface-coated titanium oxide (C) is preferably 20 or more, and more preferably 25 or more. When a relative permittivity is 20 or more, the insulation layer having a high relative permittivity tends to be obtained. In the present embodiment, the relative permittivity of surface-coated titanium oxide (C) is the value at 10 GHz measured by the cavity resonator method. In the present embodiment, the relative permittivity of surface-coated titanium oxide (C) can be calculated using the Bruggeman formula (law of mixture).

The dissipation factor of surface-coated titanium oxide (C) is preferably 0.01 or less, and more preferably 0.008 or less. When a dissipation factor is 0.01 or less, the insulation layer having a low dissipation factor tends to be obtained. In the present embodiment, the dissipation factor of surface-coated titanium oxide (C) is the value at 10 GHz measured by the cavity resonator method. In the present embodiment, the dissipation factor of surface-coated titanium oxide (C) can be calculated using the Bruggeman formula (law of mixture).

The total amount (coating amount) of the organic layer and the inorganic oxide layer is preferably, in total, 0.1 to 10 mass %, and more preferably 1 to 8 mass %, based on 100 mass % of surface-coated titanium oxide (C), in view of more inhibiting the hydrolysis of cyanate ester compound (A), more enhancing the close contact with resin components, more reducing the aggregation of surface-coated titanium oxide (C) in the resin composition, more enhancing the dispersibility, and obtaining excellent dielectric characteristics (high permittivity and low dissipation factor), and heat resistance.

Examples of the core particle include titanium monoxide (TiO), dititanium trioxide (Ti₂O₃), and titanium dioxide (TiO₂). Of these, titanium dioxide is preferable. For titanium dioxide, those having rutile-type or anatase-type crystal structure are preferable, and those having rutile-type crystal structure are more preferable.

The median particle size (D50) of core particles is preferably 0.10 to 0.45 μm, and more preferably 0.15 to 0.25 μm, in view of the dispersibility. In the present embodiment, the median particle size (D50) of core particles is determined from the average value of particle sizes of primary particles within a single particle.

Surface-coated titanium oxide (C) can be typically obtained by coating the surface of core particles with an organic layer or an inorganic oxide layer by using a surface treatment agent. Further, an organic layer and/or an inorganic oxide layer may further coat the surface of the organic layer or the inorganic oxide layer coating the surface of core particles by using the surface treatment agent. It is preferable that surface-coated titanium oxide (C) have an inorganic oxide layer coating the surface of core particles and further an organic layer on the surface of the inorganic oxide layer, in view of allowing cyanate ester compound (A) and maleimide compound (B) to be more compatible, and obtaining the resin composition having more favorable thermal characteristics during curing (low coefficient of thermal expansion, moisture absorption and heat resistance, and high glass transition temperature) and more favorable dielectric characteristics (high permittivity and low dissipation factor), and further obtaining the insulation layer having a further suitable surface hardness. The coating method include inorganic treatments and organic treatments. The surface treatment agents can be used singly, or two or more thereof can also be used in combination.

Examples of the surface treatment agent used for an inorganic treatment include oxoacids, metal salts, oxides, hydroxides, and hydrates of oxides, of metals such as aluminum, silicon, zirconium, tin, titanium, antimony, zinc, cobalt, and manganese (examples of the oxoacids include silicic acid and aluminic acid, and examples of the metal salts include sodium silicate and sodium aluminate). Surface-coated titanium oxide (C) obtained by an inorganic treatment has an inorganic oxide layer on the surface of titanium oxide particles, the surface of an inorganic oxide layer, or the surface of an organic layer to be described later.

Examples of the surface treatment agent used for an organic treatment include organosilicon compounds such as organosilane, silane coupling agent, and organopolysiloxane; organotitanium compounds such as titanate coupling agent; organic matters such as organic acid, polyol, and alkanolamine. Surface-coated titanium oxide (C) to be obtained by an organic treatment has an organic layer on the surface of titanium oxide particles, the surface of an organic layer, or the surface of an inorganic oxide layer.

Examples of the organosilane include alkoxysilanes such as n-propyltrimethoxysilane, n-propyltriethoxysilane, hexyltrimethoxysilane, hexyltriethoxysilane, octyltrimethoxysilane, decyltrimethoxysilane, 3-chloropropyltriethoxysilane, phenyltriethoxysilane, and trifluoropropyltrimethoxysilane.

Examples of the silane coupling agent include aminosilanes such as 3-aminopropyltriethoxysilane, N-2-(aminoethyl)-3-aminopropyltriethoxysilane, and N-phenyl-3-aminopropyltrimethoxysilane; epoxysilanes such as 3-glycidoxypropyltrimethoxysilane, and 2-(3,4-epoxycyclohexyl)ethyltrimethoxysilane; methacrylsilanes such as 3-(methacryloyloxypropyl)trimethoxysilane; vinylsilanes such as vinyltrimethoxysilane, vinyltriethoxysilane, and vinyltrichlorosilane; and mercaptosilanes such as 3-mercaptopropyltrimethoxysilane.

Organopolysiloxane is preferably a silicone oil, which can form a more uniform organic layer. Examples of the silicone oil include alkyl silicone, alkyl hydrogen silicone, alkoxy silicone, and modified silicones.

Examples of the alkyl silicone include dimethyl silicone.

Examples of the alkyl hydrogen silicone include methyl hydrogen silicone, and ethyl hydrogen silicone.

Alkoxy silicone is preferably a silicone compound containing an alkoxysilyl group, in which an alkoxy group bonds a silicon atom directly or via a divalent hydrocarbon group. Examples of such a silicone compound include straight-chain organopolysiloxanes having a straight-, cyclic-, network-, and partially branched-chain. Of these, straight-chain organopolysiloxanes are preferable, and organopolysiloxanes having a molecular structure in which an alkoxy group directly bonds the silicone backbone are more preferable. Examples of the alkoxy silicone include methoxy silicone, and ethoxy silicone.

Examples of the modified silicone include amino-modified silicone, epoxy-modified silicone, and mercapto-modified silicone.

Examples of the titanate coupling agent include isopropyl triisostearoyl titanate, isopropyl dimethacryl isostearoyl titanate, and isopropyl tridodecyl benzene sulfonyl titanate.

Examples of the organic acid include adipic acid, terephthalic acid, lauric acid, myristic acid, palmitic acid, stearic acid, polyhydroxystearic acid, oleic acid, salicylic acid, malic acid, and maleic acid, and metal salts thereof.

Examples of the polyol include trimethylolethane, trimethylolpropane, ditrimethylolpropane, trimethylolpropane ethoxylate, and pentaerythritol.

Examples of the alkanolamine include monoethanolamine, monopropanolamine, diethanolamine, dipropanolamine, triethanolamine, and tripropanolamine.

Surface-coated titanium oxide (C) has an inorganic oxide layer on the surface of titanium oxide particles, wherein the inorganic oxide layer is preferably one or more selected from the group consisting of a layer containing silica, a layer containing zirconia, and a layer containing alumina, and the inorganic oxide layer is more preferably one or more selected from the group consisting of a layer containing silica and a layer containing alumina, in view of allowing cyanate ester compound (A) and maleimide compound (B) to be more compatible, and obtaining the resin composition having more favorable thermal characteristics during curing (low coefficient of thermal expansion, moisture absorption and heat resistance, and high glass transition temperature) and more favorable dielectric characteristics (high permittivity and low dissipation factor), and further obtaining the insulation layer having a more suitable surface hardness.

Surface-coated titanium oxide (C) can have two or more inorganic oxide layers. When surface-coated titanium oxide (C) has two or more inorganic oxide layers, it is preferable that the two or more inorganic oxide layers have the features such that the inorganic oxide layer positioned at the closer side to a titanium oxide particle can further inhibit the hydrolysis of cyanate ester compound (A) by mainly the titanium oxide particle, which is the core particle, and such that the inorganic oxide layer positioned at the farther side from the titanium oxide particle can more enhance mainly the close contact with resin components, more reduce the aggregation of surface-coated titanium oxide (C) in the resin composition, and more enhance the dispersibility.

From such a viewpoint, when surface-coated titanium oxide (C) has two or more inorganic oxide layers, it is preferable that the inorganic oxide layer positioned at the closer side to the core particle be one or more selected from the group consisting of a layer containing silica and a layer containing zirconia, and that the inorganic oxide layer positioned at the farther side from the core particle contain a layer containing alumina, and it is more preferable that the inorganic oxide layer positioned at the closer side to the core particle be a layer containing silica, and that the inorganic oxide layer positioned at the farther side to the core particle be a layer containing alumina.

The inorganic oxide layer is preferably, in total, 0.1 to 10 mass %, more preferably 0.3 to 7.5 mass %, further preferably 0.4 to 5.0 mass %, and furthermore preferably 0.5 to 4.0 mass %, based on 100 mass % of surface-coated titanium oxide (C), in view of even more inhibiting the hydrolysis of cyanate ester compound (A), and obtaining excellent heat resistance.

The inorganic oxide layer acts to inhibit the hydrolysis of cyanate ester compound (A) by titanium oxide, which is the core particle. On the other hand, silica, zirconia, and alumina, which are inorganic oxides, are hydrous inorganic matters and have thus comparatively high water absorbency among inorganic oxides, whereby moisture tends to easily evaporate during reflow operation. The evaporated moisture causes to induce the hydrolysis of cyanate ester compound (A). Considering this, it is preferable that surface-coated titanium oxide (C) have an organic layer on the surface of the inorganic oxide layer. The organic layer further reduces the water absorption of titanium oxide, which is the core particle, and the inorganic oxide layer, thereby further inhibiting the hydrolysis of cyanate ester compound (A). For this reason, the moisture evaporation from the insulation layer during reflow operation can be inhibited. Further, the organic layer reduces the aggregation of surface-coated titanium oxide (C) in the resin composition, thereby providing the effect of further enhancing the dispersibility.

The organic layer is preferably the layer obtained by surface treating with an organosilicon compound, in view of even more reducing the aggregation of surface-coated titanium oxide (C) in the resin composition, even more enhancing the dispersibility, and reducing the water absorbency of a laminate by more favorable water repellency.

The organosilicon compound preferably contains one or more selected from the group consisting of silane coupling agents, organosilane, and organopolysiloxane. The organic layer to be obtained by surface treating with these surface treatment agents is a layer having the siloxane structure. The layer having the siloxane structure tends to furthermore reduce the aggregation of surface-coated titanium oxide (C) in the resin composition, furthermore enhance the dispersibility, and reduce the water absorbency of a laminate by further excellent water repellency. The organopolysiloxane is preferably silicone oils, in view of forming a more uniform layer having the siloxane structure and further providing the effects described above, and dimethyl silicone is more preferable among silicone oils. In this case, a surface treatment agent other than the above can be used as long as the organic layer becomes a layer having the siloxane structure.

The organic layer is preferably, in total, 0.1 to 10 mass %, more preferably 0.5 to 7.5 mass %, further preferably 0.6 to 6.0 mass %, and furthermore preferably 0.7 to 5.0 mass %, based on 100 mass % of surface-coated titanium oxide (C), in view of even more reducing the aggregation of surface-coated titanium oxide (C) in the resin composition, and even more enhancing the dispersibility.

When surface-coated titanium oxide (C) has the inorganic oxide layer and the organic layer, the coating layer of surface-coated titanium oxide (C) can be a two-layer structure of the inorganic oxide layer and the organic layer. Such a layer structure provides the effect of inhibiting catalytic activity of titanium oxide (e.g., photocatalytic activity and metal catalytic activity) and the water repelling effect. In this case, the inorganic oxide layer is preferably one or more selected from the group consisting of a layer containing silica, a layer containing zirconia, and a layer containing alumina, and more preferably a layer containing alumina, in view of further inhibiting the catalytic activity of titanium oxide while further enhancing the affinity with the resin. The organic layer preferably has the siloxane structure due to excellent heat resistance and chemical stability. When such a surface-coated titanium oxide (C) is used, the hydrolysis of cyanate ester compound (A) can be even more inhibited, and the close contact with resin components even more enhances; thus, the aggregation of surface-coated titanium oxide (C) in the resin composition can be even more reduced thereby even more enhancing the dispersibility, and cyanate ester compound (A) and maleimide compound (B) are even more compatible. Accordingly, the resin composition having more favorable thermal characteristics during curing (low coefficient of thermal expansion, moisture absorption and heat resistance, and high glass transition temperature) and even more favorable dielectric characteristics (high permittivity and low dissipation factor) can be obtained, and further the insulation layer having an even more suitable surface hardness can be obtained.

Such a surface-coated titanium oxide (C) can be a commercial product. Examples of the commercial product include R-22L, R-11P, and R-39 (these are all product names, SAKAI CHEMICAL INDUSTRY CO., LTD.)

When surface-coated titanium oxide (C) has the inorganic oxide layer and the organic layer, it is preferable that the inorganic oxide layer positioned at the closer side to the core particle, the next inorganic oxide layer, and the organic layer positioned at the farthest side from the core particle be a layer containing silica, a layer containing alumina, and a layer having the siloxane structure, respectively. When such a surface-coated titanium oxide (C) is used, the hydrolysis of cyanate ester compound (A) can be even more inhibited, and the close contact with resin components even more enhances; thus, the aggregation of surface-coated titanium oxide (C) in the resin composition can be even more reduced thereby even more enhancing the dispersibility, and cyanate ester compound (A) and maleimide compound (B) are even more compatible. Accordingly, the resin composition having even more favorable thermal characteristics during curing (low coefficient of thermal expansion, moisture absorption and heat resistance, and high glass transition temperature) and even more favorable dielectric characteristics (high permittivity and low dissipation factor) can be obtained, and further the insulation layer having an even more suitable surface hardness can be obtained.

Such a surface-coated titanium oxide (C) can be a commercial product. Examples of the commercial product include CR-63 (product name, ISHIHARA SANGYO KAISHA, LTD.)

The content of surface-coated titanium oxide (C) is preferably 50 to 500 parts by mass, preferably 60 to 450 parts by mass, more preferably 70 to 400 parts by mass, and even further preferably 75 to 350 parts by mass, based on 100 parts by mass of the total resin solid content in the resin composition. The content of surface-coated titanium oxide (C) can be 300 parts by mass or less, 250 parts by mass or less, 200 parts by mass or less. When the content of surface-coated titanium oxide (C) is within the above range, cyanate ester compound (A) and maleimide compound (B) are even more compatible, so that the resin composition having even more favorable thermal characteristics during curing (low coefficient of thermal expansion, moisture absorption and heat resistance, and high glass transition temperature) and even more favorable dielectric characteristics (high permittivity and low dissipation factor) can be obtained, and furthermore the insulation layer having a suitable surface hardness tends to be obtained.

### <Thermosetting Resin or Compound>

The resin composition of the present embodiment preferably further contains one or more thermosetting resins or compounds (hereinafter, referred to as the “thermosetting resin”) selected from the group consisting of epoxy compounds, phenolic compounds, modified polyphenylene ether compounds, alkenyl-substituted nadiimide compounds, oxetane resins, benzoxazine compounds, and compounds having a polymerizable unsaturated group, in view of the much higher compatibility thereof with cyanate ester compound (A) and maleimide compound (B) to even more disperse surface-coated titanium oxide (C), and obtaining the resin composition having even more favorable thermal characteristics during curing (low coefficient of thermal expansion, moisture absorption and heat resistance, and high glass transition temperature) and more favorable dielectric characteristics (high permittivity and low dissipation factor). The thermosetting resins can be used singly, or two or more thereof can also be used in combination.

The thermosetting resin is preferably one or more selected from the group consisting of epoxy compounds, phenolic compounds, modified polyphenylene ether compounds, and compounds having a polymerizable unsaturated group, and more preferably one or more selected from the group consisting of epoxy compounds and modified polyphenylene ether compounds, in view of the much higher compatibility thereof with cyanate ester compound (A) and maleimide compound (B) to even more disperse surface-coated titanium oxide (C), and obtaining the resin composition having even more favorable thermal characteristics during curing (low coefficient of thermal expansion, moisture absorption and heat resistance, and high glass transition temperature) and even more favorable dielectric characteristics (high permittivity and low dissipation factor).

The content of the thermosetting resin is preferably, in total, 10 to 70 parts by mass, more preferably 20 to 60 parts by mass, and further preferably 30 to 50 parts by mass, based on 100 parts by mass of the total resin solid content in the resin composition, in view of the still higher compatibility thereof with cyanate ester compound (A) and maleimide compound (B) to further disperse surface-coated titanium oxide (C), and obtaining the resin composition having even more favorable thermal characteristics during curing (low coefficient of thermal expansion, moisture absorption and heat resistance, and high glass transition temperature) and dielectric characteristics (low dissipation factor).

### (Epoxy Compound)

The resin composition of the present embodiment can contain an epoxy compound.

For the epoxy compound, a known compound can be appropriately used as long as the compound has one or more epoxy groups in a molecule, and the kind thereof is not particularly limited. The number of epoxy groups in a molecule of the epoxy compound is one or more, and preferably two or more. The epoxy compounds can be used singly, or two or more thereof can also be used in combination.

For the epoxy compound, conventionally known epoxy compounds and epoxy resins can be used. Examples include biphenyl aralkyl-type epoxy resins, naphthalene-type epoxy resins, bisnaphthalene-type epoxy resins, polyfunctional phenol-type epoxy resins, naphthylene ether-type epoxy resins, phenol aralkyl-type epoxy resins, phenol novolac-type epoxy resins, cresol novolac-type epoxy resins, xylene novolac-type epoxy resins, naphthalene skeleton-modified novolac-type epoxy resins, dicyclopentadiene novolac-type epoxy resins, biphenyl novolac-type epoxy resins, phenol aralkyl novolac-type epoxy resins, naphthol aralkyl novolac-type epoxy resins, aralkyl novolac-type epoxy resins, aromatic hydrocarbon formaldehyde-type epoxy compounds, anthraquinone-type epoxy compounds, anthracene-type epoxy resins, naphthol aralkyl-type epoxy compounds, dicyclopentadiene-type epoxy resins, ZYLOCK-type epoxy compounds, bisphenol A-type epoxy resins, bisphenol E-type epoxy resins, bisphenol F-type epoxy resins, bisphenol S-type epoxy resins, bisphenol A novolac-type epoxy resins, phenol-type epoxy compounds, biphenyl-type epoxy resins, aralkyl novolac-type epoxy resins, triazine skeleton epoxy compounds, triglycidyl isocyanurate, alicyclic epoxy resins, polyol-type epoxy resins, glycidylamine, glycidyl-type ester resins, compounds obtained by epoxidating a double bond of a double bond-containing compound such as butadiene, and compounds obtained by reaction of hydroxy group-containing silicone resins and epichlorohydrin.

Of these, the epoxy compound preferably contains one or more selected from the group consisting of biphenyl aralkyl-type epoxy resins, naphthalene-type epoxy resins, and naphthylene ether-type epoxy resins, and more preferably naphthalene-type epoxy resins, in view of the still higher compatibility thereof with cyanate ester compound (A) and maleimide compound (B) to further disperse surface-coated titanium oxide (C), and obtaining the resin composition having even more favorable thermal characteristics during curing (low coefficient of thermal expansion, moisture absorption and heat resistance, and high glass transition temperature) and even more favorable dielectric characteristics (high permittivity and low dissipation factor).

The naphthalene-type epoxy resin can be a commercial product, and examples include EPICLON (registered trademark) EXA-4032-70M, and EPICLON (registered trademark) HP-4710 (all product names, DIC Corporation).

The content of the epoxy compound is preferably 1 to 50 parts by mass, more preferably 5 to 40 parts by mass, and further preferably 10 to 30 parts by mass, based on 100 parts by mass of the total of resin solid contents in the resin composition. When a content of the epoxy compound is within the above range, the adhesivity, flexibility and the like tend to be more excellent.

### (Phenolic Compound)

The resin composition of the present embodiment can contain a phenolic compound.

For the phenolic compound, a known compound can be appropriately used as long as the compound has two or more phenolic hydroxy groups in one molecule, and the kind thereof is not particularly limited. The phenolic compounds can be used singly, or two or more thereof can also be used in combination.

Examples of the phenolic compound include cresol novolac-type phenolic resins, biphenyl aralkyl-type phenolic resins represented by the formula (4), naphthol aralkyl-type phenolic resins represented by the formula (5), aminotriazine novolac-type phenolic resins, naphthalene-type phenolic resins, phenol novolac resins, alkylphenol novolac resins, bisphenol A-type novolac resins, dicyclopentadiene-type phenolic resins, ZYLOCK-type phenolic resins, terpene-modified phenolic resins, and polyvinylphenols.

Of these, in view of obtaining excellent formability and surface hardness, one or more selected from the group consisting of cresol novolac-type phenolic resins, biphenyl aralkyl-type phenolic resins represented by the formula (4), naphthol aralkyl-type phenolic resins represented by the formula (5), aminotriazine novolac-type phenolic resins, and naphthalene-type phenolic resins are preferable, and one or more selected from the group consisting of biphenyl aralkyl-type phenolic resins represented by the formula (4) and naphthol aralkyl-type phenolic resins represented by the formula (5) are more preferable.

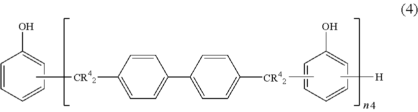

In the formula (4), R⁴ each independently represents a hydrogen atom or a methyl group, and n4 is an integer of 1 to 10.

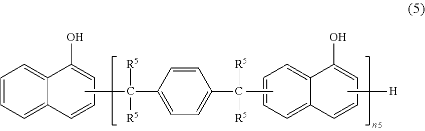

In the formula (5), R⁵ each independently represents a hydrogen atom or a methyl group, and n₅ is an integer of 1 to 10.

The content of the phenolic compound is preferably 1 to 50 parts by mass, more preferably 5 to 40 parts by mass, and further preferably 10 to 30 parts by mass, based on 100 parts by mass of the total resin solid content in the resin composition. When the content of the phenolic compound is within the above range, the adhesivity, flexibility and the other properties tend to be more excellent.

### (Modified Polyphenylene Ether Compound)

The resin composition of the present embodiment can contain a modified polyphenylene ether compound, in view of further enhancing the characteristics relating to the low dissipation factor of the resin composition of the present embodiment.

Herein, the “modified” of the modified polyphenylene ether compound means the polyphenylene ether compound is substituted at a part or all of the terminals thereof with a reactive functional group such as a carbon-carbon unsaturated double bond. Herein, the “polyphenylene ether” refers to the compound having the polyphenylene ether skeleton represented by the following formula (X1). For the modified polyphenylene ether compound, a known compound can be appropriately used and is not particularly limited as long as the polyphenylene ether compound is modified at a part or all of the terminals thereof. The modified polyphenylene ether compounds can be used singly, or two or more thereof can also be used in combination.

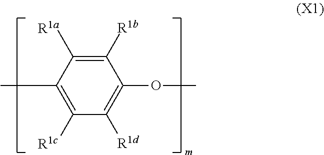

In the formula (X1), R^{1a}, R^{1b}, R^{1c}, and R^{1d} each independently represent a hydrogen atom, an alkyl group, an aryl group, an alkenyl group, an alkynyl group, a formyl group, an alkyl carbonyl group, an alkenyl carbonyl group, or an alkynyl carbonyl group, m represents the number of repeat units and an integer of 1 or more.

Example of the substituent containing a carbon-carbon unsaturated double bond include (i) the substituent represented by the following formula (X2), and (ii) the substituent represented by the following formula (X3).

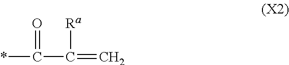

In the formula (X2), R^{a} represents a hydrogen atom or an alkyl group, and * represents a dangling bond.

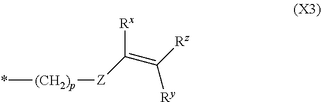

In the formula (X3), R^{x}, R^{y} and R^{z} each independently represent a hydrogen atom or an alkyl group (e.g., alkyl groups having 1 to 5 carbon atoms such as a methyl group and an ethyl group), Z represents an arylene group, p represents an integer of 0 to 10, and * represents a dangling bond.

Of these, the substituent containing a carbon-carbon unsaturated double bond is preferably the substituent represented by the formula (X3), in view of the much higher compatibility with cyanate ester compound (A) and maleimide compound (B) to even more disperse surface-coated titanium oxide (C), and obtaining the resin composition having even more favorable thermal characteristics during curing (low coefficient of thermal expansion, moisture absorption and heat resistance, and high glass transition temperature) and even more favorable dielectric characteristics (high permittivity and low dissipation factor).

In the formula (X3), Z represents an arylene group. Examples of the arylene group include monocyclic aromatic groups such as a phenylene group, and polycyclic aromatic groups such as a naphthalene ring. Further, the hydrogen atom bonding an aromatic ring in the arylene group can be replaced with a functional group (e.g., an alkenyl group, an alkynyl group, a formyl group, an alkyl carbonyl group, an alkenyl carbonyl group, or an alkynyl carbonyl group).

Specific examples of the substituent represented by the formula (X3) include the substituent represented by the following formula (X3a), and the substituent represented by the following formula (X3b).

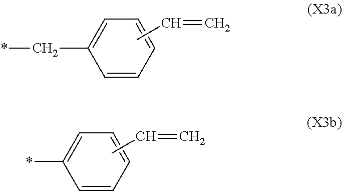

In the formula (X3a) and the formula (X3b), * represents a dangling bond.

Of these, the substituent represented by the formula (X3a) is preferable, in view of the higher compatibility with cyanate ester compound (A) and maleimide compound (B) to further disperse surface-coated titanium oxide (C), and obtaining the resin composition having more favorable thermal characteristics during curing (low coefficient of thermal expansion, moisture absorption and heat resistance, and high glass transition temperature) and even more favorable dielectric characteristics (high permittivity and low dissipation factor).

The modified polyphenylene ether compound is preferably the compound represented by the following formula (II), in view of the much higher compatibility with cyanate ester compound (A) and maleimide compound (B) to further disperse surface-coated titanium oxide (C), and obtaining the resin composition having more favorable thermal characteristics during curing (low coefficient of thermal expansion, moisture absorption and heat resistance, and high glass transition temperature) and even more favorable dielectric characteristics (high permittivity and low dissipation factor).

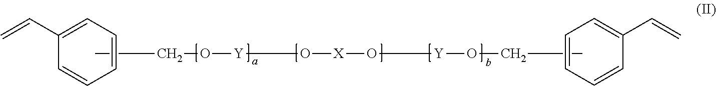

In the formula (II), —(O—X—O)— is the structure represented by the following formula (III) or the following formula (IV); —(O—Y)— or —(Y—O)— is the structure represented by the following formula (V), and when a plurality of —(O—Y)— and/or —(Y—O)— are sequentially arranged, a single kind of the structure can be arranged, or two or more kinds of the structure can be regularly or irregularly arranged; and a and b each independently represent an integer of 0 to 100, and at least one of a and b is not 0.

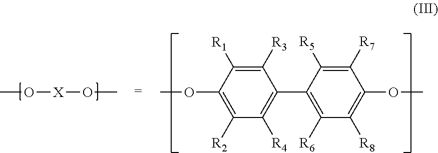

In the formula (III), R₁, R₂, R₃, R₇, and R₈ each independently represent a halogen atom, an alkyl group having 6 or less carbon atoms (e.g., a methyl group, an ethyl group, an n-propyl group, an isopropyl group, an n-butyl group, an isobutyl group, a t-butyl group, an n-pentyl group, and an n-hexyl group), or a phenyl group. Of these, R₁, R₂, R₃, R₇, and R₈ are preferably an alkyl group having 6 or less carbon atoms, preferably an alkyl group having 3 or less carbon atoms, and further preferably a methyl group, in view of the much higher compatibility with cyanate ester compound (A) and maleimide compound (B) to even more disperse surface-coated titanium oxide (C), and obtaining the resin composition having even more favorable thermal characteristics during curing (low coefficient of thermal expansion, moisture absorption and heat resistance, and high glass transition temperature) and even more favorable dielectric characteristics (high permittivity and low dissipation factor). In the formula (III), R₄, R₅, and R₆ each independently represent a hydrogen atom, a halogen atom, an alkyl group having 6 or less carbon atoms (e.g., a methyl group, an ethyl group, an n-propyl group, an isopropyl group, an n-butyl group, an isobutyl group, a t-butyl group, an n-pentyl group, and an n-hexyl group), or a phenyl group. Of these, R₄, R₅, and R₆ are preferably a hydrogen group or an alkyl group having 6 or less carbon atoms, more preferably a hydrogen atom or an alkyl group having 3 or less carbon atoms, and further preferably a hydrogen atom or a methyl group, in view of the much higher compatibility with cyanate ester compound (A) and maleimide compound (B) to even more disperse surface-coated titanium oxide (C), and obtaining the resin composition having even more favorable thermal characteristics during curing (low coefficient of thermal expansion, moisture absorption and heat resistance, and high glass transition temperature) and even more favorable dielectric characteristics (high permittivity and low dissipation factor). The structure represented by the formula (III) is preferably the structure represented by the following formula (VI), in view of more enhancing the effects of the present invention.

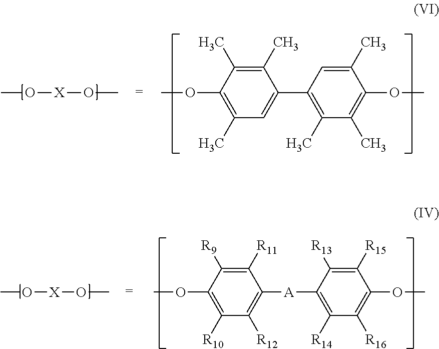

In the formula (IV), R₉, R₁₀, R₁₁, R₁₂, R₁₃, R₁₄, R₁₅, and R₁₆ (R₉ to R₁₆) each independently represent a hydrogen atom, a halogen atom, alkyl group having 6 or less carbon atoms (e.g., a methyl group, an ethyl group, an n-propyl group, an isopropyl group, an n-butyl group, an isobutyl group, a t-butyl group, an n-pentyl group, and an n-hexyl group), or a phenyl group. Of these, R₉ to R₁₆ are preferably a hydrogen atom, or an alkyl group having 6 or less carbon atoms, and more preferably a hydrogen atom, or an alkyl group having 3 or less carbon atoms, and further preferably a hydrogen atom, or a methyl group, in view of the still higher compatibility with cyanate ester compound (A) and maleimide compound (B) to still more disperse surface-coated titanium oxide (C), and obtaining the resin composition having still more favorable thermal characteristics during curing (low coefficient of thermal expansion, moisture absorption and heat resistance, and high glass transition temperature) and even more favorable dielectric characteristics (high permittivity and low dissipation factor). -A- represents a straight-, branched-, or cyclic-chain divalent hydrocarbon group having 20 or less carbon atoms. When R₉ to R₁₆ each independently represent a hydrogen atom, or a methyl group, the structure represented by the formula (IV) is preferably the structure represented by the following formula (VII) or (VIII), in view of more enhancing the effects of the present invention.

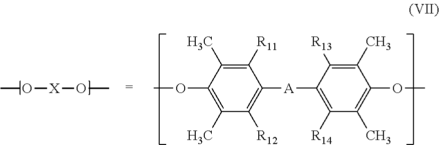

In the formula (VII), R₁₁, R₁₂, R₁₃, and R₁₄ represent a hydrogen atom, or a methyl group, -A- represents a straight-, branched-, or cyclic-chain divalent hydrocarbon group having 20 or less carbon atoms.

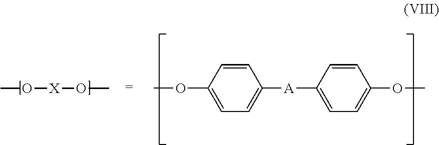

In the formula (VIII), -A- represents a straight-, branched-, or cyclic-chain divalent hydrocarbon group having 20 or less carbon atoms.

In the formula (IV), the formula (VII), and the formula (VIII), examples of -A- include divalent hydrocarbon groups such as a methylene group, an ethylidene group, a 1-methylethylidene group, a 1,1-propylidene group, a 1,4-phenylenebis(1-methylethylidene) group, a 1,3-phenylenebis(1-methylethylidene) group, a phenylmethylene group, a naphthylmethylene group, a 1-phenylethylidene group, and a cyclohexylidene group. Of these, in view of more enhancing the effects of the present invention, -A- is preferably one selected from the group consisting of a methylene group, an ethylidene group, a 1-methylethylidene group, a 1,1-propylidene group, a 1,4-phenylenebis(1-methylethylidene) group, a 1,3-phenylenebis(1-methylethylidene) group, a phenylmethylene group, a naphthylmethylene group, a 1-phenylethylidene group, and a cyclohexylidene group.

In the formula (II), —(O—Y)— or —(Y—O)— is represented by the following formula (V).

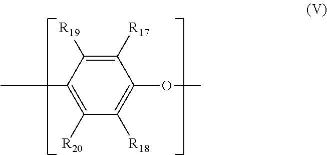

In the formula (V), R₁₇ and R₁₈ each independently represent a halogen atom, an alkyl group having 6 or less carbon atoms (e.g., a methyl group, an ethyl group, an n-propyl group, an isopropyl group, an n-butyl group, an isobutyl group, a t-butyl group, an n-pentyl group, and an n-hexyl group), or a phenyl group. Of these, R₁₇ and Ris are preferably an alkyl group having 6 or less carbon atoms, more preferably an alkyl group having 3 or less carbon atoms, and further preferably a methyl group, in view of the much higher compatibility with cyanate ester compound (A) and maleimide compound (B) to even more disperse surface-coated titanium oxide (C), and obtaining the resin composition having even more favorable thermal characteristics during curing (low coefficient of thermal expansion, moisture absorption and heat resistance, and high glass transition temperature) and even more favorable dielectric characteristics (high permittivity and low dissipation factor). In the formula (V), R₁₉, and R₂₀ each independently represent a hydrogen atom, a halogen atom, an alkyl group having 6 or less carbon atoms (e.g., a methyl group, an ethyl group, an n-propyl group, an isopropyl group, an n-butyl group, an isobutyl group, a t-butyl group, an n-pentyl group, and an n-hexyl group), or a phenyl group. Of these, R₁₉, and R₂₀ are preferably a hydrogen atom, or an alkyl group having 6 or less carbon atoms, more preferably a hydrogen atom, or an alkyl group having 3 or less carbon atoms, and further preferably a hydrogen atom, or a methyl group, in view of the still higher compatibility with cyanate ester compound (A) and maleimide compound (B) to still more disperse surface-coated titanium oxide (C), and obtaining the resin composition having still more favorable thermal characteristics during curing (low coefficient of thermal expansion, moisture absorption and heat resistance, and high glass transition temperature) and further excellent dielectric characteristics (high permittivity and low dissipation factor). In the formula (V), it is preferable that R₁₇ and R₁₈ be a methyl group, and R₁₉ and R₂₀ are each independently a hydrogen atom, or a methyl group, in view of the still higher compatibility with cyanate ester compound (A) and maleimide compound (B) to still more disperse surface-coated titanium oxide (C), and obtaining the resin composition having still more favorable thermal characteristics during curing (low coefficient of thermal expansion, moisture absorption and heat resistance, and high glass transition temperature) and still more favorable dielectric characteristics (high permittivity and low dissipation factor). In this case, the structure represented by the formula (V) is more preferably the structure represented by the following formula (IX) or (X), in view of more enhancing the effects of the present invention.

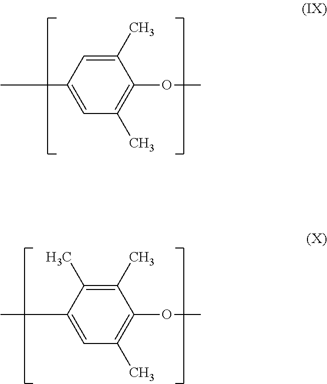

In the formula (II), a and b each independently represent an integer of 0 to 100, and at least one of a and b is not 0. a and b each independently preferably represent an integer of 1 or more and 50 or less, and more preferably represent an integer of 1 or more and 30 or less, in view of the much higher compatibility with cyanate ester compound (A) and maleimide compound (B) to even more disperse surface-coated titanium oxide (C), and obtaining the resin composition having even more favorable thermal characteristics during curing (low coefficient of thermal expansion, moisture absorption and heat resistance, and high glass transition temperature) and even more favorable dielectric characteristics (high permittivity and low dissipation factor).

In the formula (II), when a and/or b is plural (two or more), a plurality of —(Y—O)— of a single kind of the structure can be arranged, or a plurality of —(Y—O)— of two or more kinds of the structure can be regularly (e.g., alternately) or irregularly (randomly) arranged.

In view of more enhancing the effects of the present invention, it is preferable in the formula (II) that —(O—X—O)— be the structure represented by the formula (VI), the formula (VII), or the formula (VIII), —(O—Y)— be the structure represented by the formula (IX) or the formula (X), and —(Y—O)— be the structure represented by the formula (IX) or the formula (X). When a and/or b is plural (two or more), the structures represented by the formula (IX) and the formula (X) can be regularly (e.g., alternately) or irregularly (randomly) arranged.

The modified polyphenylene ether compound can be a single kind, or composed of two or more kinds with different structures.

The number average molecular weight in terms of polystyrene of the modified polyphenylene ether compound by GPC method is preferably 500 or more and 7,000 or less, and preferably 1,000 or more and 3,000 or less, in view of the still higher compatibility with cyanate ester compound (A) and maleimide compound (B) to still more disperse surface-coated titanium oxide (C), and obtaining the resin composition having still more favorable thermal characteristics during curing (low coefficient of thermal expansion, moisture absorption and heat resistance, and high glass transition temperature) and still more favorable dielectric characteristics (high permittivity and low dissipation factor). When the number average molecular weight is 500 or more, stickiness when the resin composition forms a coating film tends to be even more inhibited. When the number average molecular weight is 7,000 or less, the solubility in a solvent tends to be even more enhanced, and when the number average molecular weight is 3,000 or less, the solubility in a solvent tends to be further enhanced.

Further, the modified polyphenylene ether compound having a minimum melt viscosity of 50,000 Pa·s or less can be used. The minimum melt viscosity is measured in accordance with a common method using a dynamic mechanical analyzer. The minimum melt viscosity is preferably 500 Pa·s or more and 50,000 Pa·s or less.

The modified polyphenylene ether compound can be a commercial product. Examples of the commercial product include OPE-2St 1200 (a polymer of the formula (II), wherein —(O—X—O)— is the structure represented by the formula (VI), and —(O—Y)— and —(Y—O)— are the structure of the formula (IX)), and OPE-2St 2200 (a polymer of the formula (II), wherein —(O—X—O)— is the structure represented by the formula (VI), and —(O—Y)— and —(Y—O)— are the structure of the formula (IX)) (these are all product names, MITSUBISHI GAS CHEMICAL COMPANY, INC.)

The modified polyphenylene ether compound can be prepared by a known method. Examples of the method for preparing a modified polyphenylene ether compound terminally modified with the substituent represented by the formula (X2) or the formula (X3) include a method including reacting a polyphenylene ether compound in which the hydrogen atom of the terminal phenolic hydroxy group is replaced with an alkali metal atom such as sodium and potassium and the compound represented by the formula (X2-1) or the formula (X3-1). More specifically, examples include the method described in Japanese Patent Laid-Open No. 2017-128718.

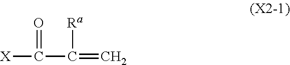

In the formula (X2-1), X represents a halogen atom, R^{a} is defined as R^{a} in the formula (X2).

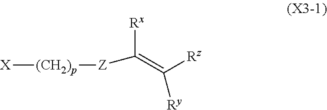

In the formula (X3-1), X represents a halogen atom, R^{x}, R^{y}, R^{z}, Z, and p are respectively defined as R^{X}, R^{y}, R^{z}, Z, and p in the formula (X3).

The preparation method (production method) of the modified polyphenylene ether compound represented by the formula (II) is not particularly limited, and, for example, such a modified polyphenylene ether compound can be produced by a step of oxidatively coupling a bifunctional phenolic compound and a monofunctional phenolic compound to obtain a bifunctional phenylene ether oligomer (oxidative coupling step), and a step of vinylbenzyl-etherifying the terminal phenolic hydroxy group of the obtained bifunctional phenylene ether oligomer (vinylbenzyl-etherification step).

In the oxidative coupling step, for example, a bifunctional phenolic compound, a monofunctional phenolic compound and a catalyst are dissolved in a solvent, and oxygen is blown thereinto while heating and stirring thereby to obtain a bifunctional phenylene ether oligomer. The bifunctional phenolic compound is not particularly limited, and examples include at least one selected from the group consisting of 2,2′,3,3′,5,5′-hexamethyl-(1,1′-bisphenol)-4,4′-diol, 4,4′-methylenebis(2,6-dimethylphenol), 4,4′-dihydroxyphenylmethane, and 4,4′-dihydroxy-2,2′-diphenylpropane. The monofunctional phenolic compound is not particularly limited, and examples include 2,6-dimethylphenol, and/or 2,3,6-trimethylphenol. The catalyst is not particularly limited, and examples include copper salts (e.g., CuCl, CuBr, CuI, CuCl₂, and CuBr₂), amines (e.g., di-n-butylamine, n-butyldimethylamine, N,N′-di-t-butylethylenediamine, pyridine, N,N,N′,N′-tetramethylethylenediamine, piperidine, and imidazole), and these can be used singly, or two or more thereof can also be used in combination. The solvent is not particularly limited, and examples include at least one selected from the group consisting of toluene, methanol, methyl ethyl ketone, and xylene.

In the vinylbenzyl-etherification step, for example, the bifunctional phenylene ether oligomer obtained in the oxidative coupling step and vinyl benzyl chloride are dissolved in a solvent and reacted by adding a base while heating and stirring, and the resulting resin is solidified to produce the modified polyphenylene ether compound. Vinyl benzyl chloride is not particularly limited, and examples include at least one selected from the group consisting of o-vinyl benzyl chloride, m-vinyl benzyl chloride, and p-vinyl benzyl chloride. The base is not particularly limited, and examples include at least one selected from the group consisting of sodium hydroxide, potassium hydroxide, sodium methoxide, and sodium ethoxide. In the vinylbenzyl-etherification step, an acid can be used to neutralize the base remaining after the reaction, and examples of the acid include, but not particularly limited to, at least one selected from the group consisting of hydrochloric acid, sulfuric acid, phosphoric acid, boric acid, and nitric acid. The solvent is not particularly limited, and examples include at least one selected from the group consisting of toluene, xylene, acetone, methyl ethyl ketone, methyl isobutyl ketone, dimethyl formamide, dimethylacetamide, methylene chloride, and chloroform. Examples of the method for solidifying a resin include a method including evaporating a solvent to dryness, and a method including mixing a reaction liquid with a poor solvent to cause reprecipitation.

The content of the modified polyphenylene ether compound is preferably 1 to 50 parts by mass, more preferably 5 to 40 parts by mass, and further preferably 10 to 30 parts by mass, based on 100 parts by mass of the total resin solid content in the resin composition. When the content of the modified polyphenylene ether compound is within the above range, the characteristics relating to the low dissipation factor and the reactivity tend to even more enhance.

### (Alkenyl-Substituted Nadiimide Compound)

The resin composition of the present embodiment can contain an alkenyl-substituted nadiimide compounds.

The alkenyl-substituted nadiimide compound is not particularly limited as long as the compound has one or more alkenyl-substituted nadiimide groups in a molecule. The alkenyl-substituted nadiimide compounds can be used singly, or two or more thereof can also be used in combination.

Examples of the alkenyl-substituted nadiimide compound include the compound represented by the following formula (2d).

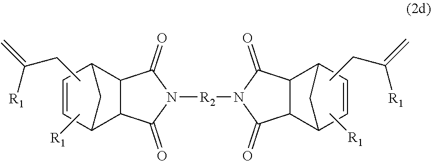

In the formula (2d), R₁ each independently represents a hydrogen atom, or an alkyl group having 1 to 6 carbon atoms (e.g., a methyl group or an ethyl group), R₂ represents an alkylene group having 1 to 6 carbon atoms, a phenylene group, a biphenylene group, a naphthylene group, or a group represented by formula (6) or formula (7).

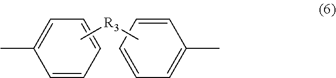

In the formula (6), R₃ represents a methylene group, an isopropylidene group, CO, O, S, or SO₂.

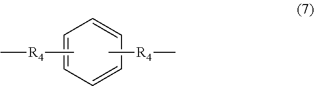

In the formula (7), R₄ each independently represents an alkylene group having 1 to 4 carbon atoms, or a cycloalkylene group having 5 to 8 carbon atoms.

The alkenyl-substituted nadiimide compound represented by the formula (2d) can be a commercial product, or a product produced in accordance with a known method can also be used. Examples of the commercial product include BANI-M, and BANI-X (all product names, Maruzen Petrochemical Co., Ltd.).

The content of the alkenyl-substituted nadiimide compound is preferably 1 to 50 parts by mass, more preferably 5 to 40 parts by mass, and further preferably 10 to 30 parts by mass, based on 100 parts by mass of the total resin solid content in the resin composition. When the content of the alkenyl-substituted nadiimide compound is within the above range, the adhesivity, heat resistance and the other properties tend to be more excellent.

### (Oxetane Resin)

The resin composition of the present embodiment can contain an oxetane resin.

Oxetane resin is not particularly limited, and a generally known resin can be used. The oxetane resins can be used singly, or two or more thereof can also be used in combination.

Examples of the oxetane resin include alkyloxetane such as oxetane, 2-methyloxetane, 2,2-dimethyloxetane, 3-methyloxetane, and 3,3-dimethyloxetane, 3-methyl-3-methoxymethyloxetane, 3,3-di(trifluoromethyl)perfluorooxetane, 2-chloromethyloxetane, 3,3-bis(chloromethyl)oxetane, biphenyl-type oxetane, OXT-101 (product name, Toagosei Co., Ltd.), and OXT-121 (product name, Toagosei Co., Ltd.).

The content of the oxetane resin is preferably 1 to 50 parts by mass, more preferably 5 to 40 parts by mass, and further preferably 10 to 30 parts by mass, based on 100 parts by mass of the total of resin solid contents in the resin composition. When a content of the oxetane resin is within the above range, the adhesivity, flexibility and the like tend to be more excellent.

### (Benzoxazine Compound)

The resin composition of the present embodiment can contain a benzoxazine compound.

The benzoxazine compound is not particularly limited as long as the compound has two or more dihydrobenzoxazine rings in a molecule, and a generally known compound can be used. The benzoxazine compounds can be used singly, or two or more thereof can also be used in combination.

Examples of the benzoxazine compound include bisphenol A-type benzoxazine BA-BXZ, bisphenol F-type benzoxazine BF-BXZ, and bisphenol S-type benzoxazine BS-BXZ (all product names, Konishi Chemical Ind. Co., Ltd.).

The content of the benzoxazine compound is preferably 1 to 50 parts by mass, more preferably 5 to 40 parts by mass, and further preferably 10 to 30 parts by mass, based on 100 parts by mass of the total of resin solid contents in the resin composition. When a content of the benzoxazine compound is within the above range, the adhesivity, flexibility and the like tend to be more excellent.

### (Compound Having a Polymerizable Unsaturated Group)

The resin composition of the present embodiment can contain a compound having a polymerizable unsaturated group.

The compound having a polymerizable unsaturated group is not particularly limited, and a generally known compound can be used. The compounds having a polymerizable unsaturated group can be used singly, or two or more thereof can also be used in combination.

Examples of the compound having a polymerizable unsaturated group include vinyl compounds such as ethylene, propylene, styrene, divinyl benzene, and divinyl biphenyl; meth(acrylates) of monohydric or polyhydric alcohol such as methyl (meth)acrylate, 2-hydroxyethyl (meth)acrylate, 2-hydroxypropyl (meth)acrylate, polypropylene glycol di(meth)acrylate, trimethylolpropane di(meth)acrylate, trimethylolpropane tri(meth)acrylate, pentaerythritol tetra(meth)acrylate, and dipentaerythritol hexa(meth)acrylate; epoxy (meth)acrylates such as bisphenol A-type epoxy (meth)acrylate, and bisphenol F-type epoxy (meth)acrylate; and benzocyclobutene resins.

The content of the compound having a polymerizable unsaturated group is preferably 1 to 50 parts by mass, more preferably 5 to 40 parts by mass, and further preferably 10 to 30 parts by mass, based on 100 parts by mass of the total of resin solid contents in the resin composition. When a content of the compound having a polymerizable unsaturated group is within the above range, the adhesivity, flexibility and the like tend to be more excellent.

### <Filler>

The resin composition of the present embodiment preferably further contains a filler different from surface-coated titanium oxide (C), in view of having further dispersibility with surface-coated titanium oxide (C) in the resin composition containing cyanate ester compound (A) and maleimide compound (B), and obtaining the resin composition having more favorable thermal characteristics during curing (low coefficient of thermal expansion, moisture absorption and heat resistance, and high glass transition temperature) and further excellent dielectric characteristics (high permittivity and low dissipation factor). The filler is not particularly limited as long as it is different from surface-coated titanium oxide (C). The fillers can be used singly, or two or more thereof can also be used in combination.

The median particle size (D50) of the filler is preferably 0.10 to 10.00 μm, and more preferably 0.30 to 5.0 μm. When a median particle size (D50) is within the above range, the filler has the even better dispersibility with surface-coated titanium oxide (C) in the resin composition containing cyanate ester compound (A) and maleimide compound (B), and the resin composition having even more favorable thermal characteristics during curing (low coefficient of thermal expansion, moisture absorption and heat resistance, and high glass transition temperature) and even more favorable dielectric characteristics (high permittivity and low dissipation factor) tends to be obtained. The median particle size (D50) of the filler is calculated in the same manner as for the median particle size (D50) of surface-coated titanium oxide (C) described above.

Examples of the filler include inorganic fillers such as silica, silicon compounds (e.g., white carbon), metal oxides (e.g., alumina, titanium white, strontium titanate (SrTiO₃), calcium titanate (CaTiO₃), titanium oxide (TiO₂) different from surface-coated titanium oxide (C), MgSiO₄, MgTiO₃, ZnTiO₃, ZnTiO₄, CaTiO₃, SrTiO₃, SrZrO₃, BaTi₂O₃, BaTi₄O₉, Ba₂Ti₉O₂₀, Ba(Ti, Sn)₉O₂₀, ZrTiO₄, (Zr, Sn) TiO₄, BaNd₂Ti₅O₁₄, BaSmTiO₁₄, Bi₂O₃—BaO—Nd₂O₃—TiO₂, La₂Ti₂O₇, barium titanate (BaTiO₃), Ba(Ti, Zr)O₃, (Ba, Sr)TiO₃, molybdenum compounds (e.g., molybdic acid, zinc molybdates such as ZnMoO₄ and Zn₃Mo₂O₉, ammonium molybdate, sodium molybdate, potassium molybdate, calcium molybdate, molybdenum disulfide, molybdenum trioxide, molybdic acid hydrates, and ammonium zinc molybdate hydrates such as (NH₄)Zn₂Mo₂O₉·(H₃O)), zinc oxide, magnesium oxide, and zirconium oxide), metal nitrides (e.g., boron nitride, silicon nitride, and aluminum nitride), metal sulfates (e.g., barium sulfate), metal hydroxides (e.g., aluminum hydroxide, heated products of aluminum hydroxide (e.g., those obtained by heat treating aluminum hydroxide and reducing a part of water of crystallization), boehmite, and magnesium hydroxide), zinc compounds (e.g., zinc borate and zinc stannate), clay, kaolin, talc, calcined clay, calcined kaolin, calcined talc, mica, E-glass, A-glass, NE-glass, C-glass, L-glass, D-glass, S-glass, M-glass G20, glass short fibers (including glass fine powders such as E glass, T glass, D glass, S glass, and Q glass), hollow glass, spherical glass, and metal microparticles formed by insulating a metal such as gold, silver, palladium, copper, nickel, iron, cobalt, zinc, Mn—Mg—Zn, Ni—Zn, Mn—Zn, carbonyl iron, Fe—Si, Fe—Al—Si, and Fe—Ni; and organic fillers, including powders of rubbers such as styrene-based, butadiene-based, and acryl-based rubbers; core/shell rubber powder; silicone resin powder; silicone rubber powder; and silicone composite powder.

Of these, the filler preferably contains one or more selected from the group consisting of silica, alumina, barium titanate, strontium titanate, calcium titanate, aluminum nitride, boron nitride, boehmite, aluminum hydroxide, zinc molybdate, silicone rubber powder, and silicone composite powder, and more preferably contains one or more selected from the group consisting of silica and zinc molybdate, in view of having better dispersibility with surface-coated titanium oxide (C) in the resin composition containing cyanate ester compound (A) and maleimide compound (B), and obtaining the resin composition having even more favorable thermal characteristics during curing (low coefficient of thermal expansion, moisture absorption and heat resistance, and high glass transition temperature) and even more favorable dielectric characteristics (high permittivity and low dissipation factor).

Examples of the silica include natural silica, fused silica, synthetic silica, fumed silica, and hollow silica. These silicas can be used singly, or two or more thereof can also be used in combination. Of these, fused silica and hollow silica are preferable, in view of having a low coefficient of thermal expansion, and excellent dispersibility in the resin composition.

Silica can be a commercial product, and examples include SC2050-MB, SC5050-MOB, SC2500-SQ, SC4500-SQ, and SC5050-MOB (all product names, Admatechs Company Limited); and SFP-130MC (product name, Denka Company Limited).

The filler can be the surface treated filler in which an inorganic oxide is formed on at least a part of the surface of the core particle of the filler. Examples of such a filler include the surface treated molybdenum compound particle (support type) in which an inorganic oxide is formed on at least a part of the surface of core particle made of a molybdenum compound.

The inorganic oxide can be provided on at least a part of the surface of the core particle of the filler. The inorganic oxide can be provided partially on the surface of the core particle of the filler, or can be provided so as to cover the entire surface of the core particle of the filler. In view of inhibiting the hydrolysis of the cyanate ester compound, it is preferable that the inorganic oxide be uniformly provided so as to cover the entire surface of the core particle of the filler, and specifically, that a film of an inorganic oxide be uniformly formed on the surface of the core particle of the filler.

The inorganic oxide is preferably those with excellent heat resistance. The kind thereof is not particularly limited, but a metal oxide is more preferable. Examples of the metal oxide include SiO₂, Al₂O₃, TiO₂, ZnO, In₂O₃, SnO₂, NiO, CoO, V₂O₃, CuO, MgO, and ZrO₂. These can be used singly, or two or more thereof can be appropriately used in combination. Of these, the metal oxide is preferably one or more selected from the group consisting of silica (SiO₂), titanium (TiO₂), alumina (Al₂O₃), and zirconia (ZrO₂), and more preferably silica, in view of heat resistance, insulation characteristic, and cost, for example.

The thickness of the inorganic oxide on the surface can be appropriately set in accordance with desired performances and is not particularly limited. In view of forming a uniform film of the inorganic oxide to provide more favorable close contact with the core particle of the filler, and more inhibiting the water absorption of the resin composition, the thickness thereof is preferably 3 to 500 nm, more preferably 5 to 200 nm, and further preferably 10 to 100 nm.

Examples of the surface treated molybdenum particle (support type) include those obtained by surface treating particles of a molybdenum compound with a silane coupling agent, and those obtained by treating the surface thereof with an inorganic oxide by the sol-gel method, liquid phase deposition method, or the like.

For the surface treated molybdenum particles, it is preferable that the inorganic oxide be provided on at least a part of the surface or the entire surface, and specifically at least on a part or the whole of the outer circumference of the core particle made of the molybdenum compound. Of such surface treated molybdenum compounds particles, it is more preferable that silica as the inorganic oxide is provided on at least a part of the surface or the entire surface, and specifically at least on a part or the whole of the outer circumference of core particles made of the molybdenum compound. The core particle made of the molybdenum compound is more preferably at least one selected from the group consisting of molybdic acid, zinc molybdate, and ammonium zinc molybdate hydrate, and more preferably zinc molybdate.

In view of the dispersibility in resin composition, the median particle size (D50) of the surface treated molybdenum compound particles is preferably 0.1 to 10 μm, more preferably 0.5 to 8 μm, further preferably 1 to 4 μm, and furthermore preferably 1 to 3 μm. The median particle size (D50) of the surface treated molybdenum compound particles is calculated in the same manner as for the median particle size (D50) of surface-coated titanium oxide (C) described above.

The core particle made of the molybdenum compound can be produced by various known methods such as crushing method and granulation method, and the production method thereof is not particularly limited. Additionally, a commercial product thereof can be used.

The production method of the surface treated molybdenum compound particle is not particularly limited, and various know techniques, including the sol-gel method, liquid phase deposition method, dip coating method, spray coating method, printing method, electroless plating method, sputtering method, vapor deposition method, ion plating method, and CVD method, can be appropriately employed to provide the inorganic oxide or a precursor thereof on the surface of the core particle made of the molybdenum compound, whereby the surface treated molybdenum compound particles can be obtained. The method for providing the inorganic oxide or a precursor thereof on the surface of the core particle made of the molybdenum compound can be either a wet method or a dry method.

A preferable example of the production method of the surface treated molybdenum compound particle is as follows: the molybdenum compound (core particles) is dispersed in a solution obtained by dissolving a metal alkoxide such as silicon alkoxide (alkoxysilane) or aluminum alkoxide in an alcohol; a mixed solution of water, alcohol, and a catalyst is added dropwise thereto while stirring to hydrolyze the alkoxide, thereby forming a film of silicon oxide or aluminum oxide as a low refractive index film on the surface of the compound; and then the resulting powder is collected by solid-liquid separation, vacuum dried, and then heat-treated. Another preferable example of the production method is as follows: the molybdenum compound (core particles) is dispersed in a solution obtained by dissolving a metal alkoxide such as silicon alkoxide or aluminum alkoxide in an alcohol; the resultant is mixed at a high temperature and a low pressure, thereby forming a film of silicon oxide or aluminum oxide on the surface of the compound; and then the resulting powder is vacuum dried and crushed. By these methods, the surface treated molybdenum compound particles having a film of a metal oxide such as silica, alumina or the others on the surface of the molybdenum compound can be obtained.

The content of the filler is preferably 50 to 300 parts by mass, preferably 70 to 200 parts by mass, and more preferably 100 to 150 parts by mass, based on 100 parts by mass of the total resin solid content in the resin composition, in view of having better dispersibility with surface-coated titanium oxide (C) in the resin composition containing cyanate ester compound (A) and maleimide compound (B), and obtaining the resin composition having even more favorable thermal characteristics during curing (low coefficient of thermal expansion, moisture absorption and heat resistance, and high glass transition temperature) and dielectric characteristics (low dissipation factor). When two or more kinds of fillers are contained, the total amount can be within the above range.

Surface-coated titanium oxide (C) and the filler are preferably contained in a volume ratio (surface-coated titanium oxide (C):filler) ranging from 15:85 to 85:15, more preferably ranging from 20:80 to 80:20, and further preferably ranging from 25:75 to 75:25. When a volume ratio is within the above range, cyanate ester compound (A) and maleimide compound (B) are more compatible, and surface-coated titanium oxide (C) and the filler tend to be more dispersed. For this reason, uneven distribution and aggregation of surface-coated titanium oxide (C) and the filler are less likely caused in the resin composition such as a resin varnish, thereby more inhibiting the hydrolysis of cyanate ester compound by the titanium oxide and obtaining the insulation layer having further excellent moisture absorption and heat resistance. Additionally, the resin composition has excellent coatability so that a molded article with a good appearance can also be obtained. Further, surface-coated titanium oxide (C) and the filler are well dispersed in the resin composition, whereby the coefficient of thermal expansion of an insulation layer can be suitably controlled, thereby efficiently forming a dielectric channel at the insulation layer. For this reason, the insulation layer having excellent moisture absorption and heat resistance and a low coefficient of thermal expansion, and having a high permittivity and a low dissipation factor tends to be suitably obtained.

In the resin composition of the present embodiment, a filler having a high permittivity can be used as the filler because such a filler can contribute to, for example, downsizing of a circuit, and downsizing of high frequency electrical components due to an increased capacitance of a capacitator. Examples of such a filler include titanium oxide (TiO₂) different from surface-coated titanium oxide (C), MgSiO₄, MgTiO₃, ZnTiO₃, ZnTiO₄, CaTiO₃, SrTiO₃, SrZrO₃, BaTi₂Os, Ba₂Ti₉O₂₀, Ba(Ti, Sn)₉O₂₀, ZrTiO₄, (Zr, Sn) TiO₄, BaNd₂Ti₅O₁₄, BaSmTiO₁₄, Bi₂O₃—BaO—Nd₂O₃—TiO₂, La₂Ti₂O₇, BaTiO₃, Ba(Ti, Zr)O₃, and (Ba, Sr) TiO₃, and metal microparticles formed by insulating metals such as gold, silver, palladium, copper, nickel, iron, cobalt, zinc, Mn—Mg—Zn, Ni—Zn, Mn—Zn, carbonyl iron, Fe—Si, Fe—Al—Si, and Fe—Ni. These fillers can be used singly, or two or more thereof can also be used in combination.

### <Silane Coupling Agent>

The resin composition of the present embodiment can further contain a silane coupling agent. When the resin composition contains a silane coupling agent, the dispersibility of surface-coated titanium oxide (C) and the filler to be blended as needed in the resin composition further enhances, thereby tending to further increase the adhesive strength of each component included in the resin composition to the base material to be described later. The silane coupling agents can be used singly, or two or more thereof can also be used in combination.

The silane coupling agent is not particularly limited, and a silane coupling agent generally used for the surface treatment of an inorganic matter can be used. Examples include aminosilane compounds (e.g., 3-aminopropyltriethoxysilane, and N-β-(aminoethyl)-γ-aminopropyltrimethoxysilane), epoxysilane compounds (e.g., 3-glycidoxy propyltrimethoxysilane), acrylsilane compounds (e.g., γ-acryloxypropyl trimethoxysilane), cationic silane compounds (e.g., N-β-(N-vinylbenzylaminoethyl)-γ-aminopropyltrimethoxysilane hydrochloride), styrylsilane compounds, phenylsilane compounds. The silane coupling agents can be used singly, or two or more thereof can also be used in combination. Of these, the silane coupling agent is preferably one or more selected from the group consisting of epoxysilane compounds and styrylsilane compounds. Examples of the epoxysilane compound include KBM-403, KBM-303, KBM-402, and KBE-403 (these are all product names, Shin-Etsu Chemical Co., Ltd.). Examples of the styrylsilane compound include KBM-1403 (product name, Shin-Etsu Chemical Co., Ltd.).

The content of the silane coupling agent is not particularly limited and can be 0.1 to 5.0 parts by mass, based on 100 parts by mass of the total of the resin solid content in the resin composition.

### <Wetting and Dispersing Agent>

The resin composition of the present embodiment can further contain a wetting and dispersing agent. When the resin composition contains a wetting and dispersing agent, the dispersibility of the filler tends to be more enhanced. The wetting and dispersing agents can be used singly, or two or more thereof can also be used in combination.

The wetting and dispersing agent can be any known dispersing agent (dispersion stabilizer) used for dispersing the filler, and examples include DISPER BYK (registered trademark)-110, 111, 118, 180, 161, 2009, 2152, 2155, W996, W9010, and W903 (all product names, BYK Japan KK).

The content of the wetting and dispersing agent is not particularly limited and is preferably 0.5 parts by mass or more and 10 parts by mass or less, based on 100 parts by mass of the total of the resin solid content in the resin composition.

### <Curing Accelerator>

The resin composition of the present embodiment can further contain a curing accelerator. The curing accelerators can be used singly, or two or more thereof can also be used in combination.

Examples of the curing accelerator include imidazoles such as triphenyl imidazole (e.g., 2,4,5-triphenyl imidazole); organic peroxides such as benzoyl peroxide, lauroyl peroxide, acetyl peroxide, para-chlorobenzoyl peroxide, di-tert-butyl-di-perphthalate; azo compounds such as azobisnitrile; tertiary amines such as N,N-dimethylbenzylamine, N,N-dimethylaniline, N,N-dimethyltoluidine, 2-N-ethylanilino ethanol, tri-n-butylamine, pyridine, quinoline, N-methylmorpholine, triethanolamine, triethylenediamine, tetramethylbutanediamine, and N-methyl piperidine; phenols such as phenol, xylenol, cresol, resorcin, and catechol; organic metal salts such as lead naphthenate, lead stearate, zinc naphthenate, zinc octylate, manganese octylate, tin oleate, dibutyltin maleate, manganese naphthenate, cobalt naphthenate, and acetylacetone iron; those obtained by dissolving these organic metal salts in a hydroxy group-containing compound such as phenol and bisphenol; and inorganic metal salts such as stannous chloride, zinc chloride, and aluminum chloride; organic tin compounds such as dioctyl tin oxide, other alkyl tins, and alkyl tin oxide; and phosphorus compounds such as triphenylphosphine, and phosphonium borate compound. Of these, triphenyl imidazoles such as 2,4,5-triphenyl imidazole and manganese octylate are preferable because these tend to accelerate the curing reaction to increase the glass transition temperature more.

The content of the curing accelerator is not particularly limited, and preferably 0.01 to 5.0 parts by mass, based on 100 parts by mass of the total resin solid content in the resin composition.

### <Solvent>

The resin composition of the present embodiment can further contain a solvent. When the resin composition contains a solvent, the viscosity of the resin composition when preparing reduces, the handleability (operability) further enhances, and the penetrating ability into a base material tends to further enhance. The solvents can be used singly, or two or more thereof can also be used in combination.

The solvent is not particularly limited as long as it can dissolve a part or all of each of the components in the resin composition. Examples include ketones (acetone, and methyl ethyl ketones), aromatic hydrocarbons (e.g., toluene, and xylene), amides (e.g., dimethyl formaldehyde), propylene glycol monomethyl ether, and acetate thereof.

### <Other Components>

The resin composition of the present embodiment can contain components other than above as long as expected characteristics are not affected. Examples of flame retardant compound include bromine compounds such as 4,4′-dibromobiphenyl; nitrogen-containing compounds such as ester phosphate, melamine phosphate, melamine, and benzoguanamine; and silicon compounds. Further, examples of various additives include an ultraviolet absorbent, an antioxidant, a photopolymerization initiator, a fluorescent whitening agent, a photosensitizing agent, a dye, a pigment, a thickener, a lubricant, a defoaming agent, a dispersing agent, a leveling agent (a surface conditioner), a brightening agent, and a polymerization inhibitor.

### [Production Method of the Resin Composition]

The production method of the resin composition of the present embodiment is not particularly limited, and for example, cyanate ester compound (A), maleimide compound (B), surface-coated titanium oxide (C), and the optional components described above, as needed, may be mixed and thoroughly stirred. During this operation, known treatments such as stirring, mixing and kneading can be carried out to homogeneously dissolve or disperse each of the components. Specifically, when the stirring and dispersing treatments are carried out using a stirring tank equipped with a stirrer having a reasonable stirring ability, the dispersibility of surface-coated titanium oxide (C) and the filler to be blended as needed in the resin composition can be enhanced. The above stirring, mixing, and kneading treatments can be appropriately carried out, for example, by using known devices such as a device for the purpose of mixing such as a ball mill, and a bead mill, or a rotation- or revolution-type mixing device.

During the preparation of the resin composition, a solvent is used as needed, so that the resin composition can be prepared in the form of a resin varnish. The kind of the solvent is not particularly limited as long as it can dissolve the resin in the resin composition. Specific examples thereof are as described above.

### [Usage]

The resin composition of the present embodiment, for example, can be suitably used as a material for a cured product, a prepreg, a film-like underfill material, a resin sheet, a laminate, a build-up material, a non-conductive film, a metal foil-clad laminate, a printed wiring board, and a fiber-reinforced composite material, or for producing a semiconductor device. Hereinafter, these will be described.

### [Cured Product]

The cured product is obtained by curing the resin composition of the present embodiment. In the production method of the cured product, for example, the resin composition of the present embodiment is fused or dissolved in a solvent, then poured into a mold and cured under typical conditions using heat, light or the like to obtain the cured product. In the case of thermosetting, the curing temperature is preferably in a range from 120 to 300° C., in view of efficiently proceeding the curing and preventing the deterioration of a cured product to be obtained.

### [Prepreg]

The prepreg of the present embodiment contains a base material and the resin composition of the present embodiment penetrating or coating the base material. The prepreg of the present embodiment can be obtained by, for example, allowing the resin composition of the present embodiment (e.g., uncured state (stage A)) to penetrate or coat a base material, and then drying at 120 to 220° C. for about 2 to 15 minutes to semi-cure (stage B). In this case, the amount of the resin composition (including the cured product of the resin composition) adhered to the base material, that is, the amount of the resin composition relative to the total amount of the semi-cured prepreg (including the surface-coated titanium oxide (C) and the filler to be blended as needed), is preferably in a range from 20 to 99 mass %. The semi-cured state (stage B) refers that each of the components included in the resin composition has not proactively started reacting (curing) while the resin composition is in a dried state, in other words, the resin composition has been heated to the extent that it is no longer viscous in order to volatilize the solvent, and the semi-cured state encompasses a state in which the resin composition is not cured while the solvent has been simply volatilized even without heating. In the present embodiment, the minimum melt viscosity of the semi-cured state (stage B) is typically 20,000 Pa·s or less. The minimum melt viscosity is, for example, 10 Pa·s or more in terms of the lower limit. In the present embodiment, the minimum melt viscosity is measured by the following method. Specifically, 1 g of a resin powder collected from the resin composition is used as a sample, and a minimum melt viscosity is measured by a rheometer (ARES-G2 (product name), TA Instruments). The minimum melt viscosity of the resin powder herein is measured using a disposable plate having a plate diameter of 25 mm in a range from 40° C. or more and 180° C. or less, under the conditions of a heating rate of 2° C./min, a frequency of 10.0 rad/sec, and a strain of 0.1%.

The base material is not particularly limited as long as it is a base material used for various printed wiring board materials. Examples of the kind of material of the base material include glass fibers (e.g., E-glass, D-glass, L-glass, S-glass, T-glass, Q-glass, UN-glass, and NE-glass), inorganic fibers other than the glass fibers (e.g., quartz), and organic fibers (e.g., polyimide, polyamide, polyester, liquid crystalline polyester, and polytetrafluoroethylene). The form of the base material is not particularly limited, and examples include woven fabrics, unwoven fabrics, rovings, chopped strand mats, and surfacing mats. These base materials can be used singly, or two or more thereof can also be used in combination. Of these base materials, woven fabrics subjected to super fiber opening treatment and filling treatment are preferable, in view of the dimensional stability. In view of moisture absorption and heat resistance, glass woven fabrics surface treated with a silane coupling agent such as epoxysilane treatment and aminosilane treatment are preferable. In view of having excellent dielectric characteristic, one or more selected from the group consisting of glass fibers such as E-glass, L-glass, NE-glass, and Q-glass are preferable.

### [Resin Sheet]

The resin sheet of the present embodiment contains the resin composition of the present embodiment. The resin sheet can also be a resin sheet with a support, which contains a support and a layer formed of the resin composition of the present embodiment disposed on the surface of the support. The resin sheet can be used as a build-up film or dry film solder resist. The production method of the resin sheet is not particularly limited, and examples include a method in which a solution of the resin composition of the present embodiment dissolved in a solvent is applied to (coating) the support and dried to obtain the resin sheet.

Examples of the support include, but not limited to, polyethylene films, polypropylene films, polycarbonate films, polyethylene terephthalate films, ethylene tetrafluoroethylene copolymer films, and mold releasing films obtained by coating the surface of any of these films with a mold release agent, organic film base materials such as polyimide films, conductive foils such as copper foil, and aluminum foil, and plate-like supports such as glass plates, SUS plates, and FRP.

Examples of the coating method (applying method) include a method in which a solution of the resin composition of the present embodiment dissolved in a solvent is applied to the support using a bar coater, a die coater, a doctor blade, or a baker applicator. After drying, the support can be released or etched from the resin sheet with the support, in which the support and the resin composition are laminated, to obtain a single layer sheet (resin sheet). For example, the solution of the resin composition of the present embodiment dissolved in a solvent is fed into a mold having a sheet-like cavity and dried to form a sheet-like shape, thereby to obtain a single layer sheet (resin sheet) without using a support.

In the manufacture of the single layer sheet or the resin sheet with the support according to the present embodiment, the drying conditions for removing the solvent are not particularly limited, but the drying is preferably carried out for 1 to 90 minutes at a temperature of 20 to 200° C., in view of easily removing the solvent in the resin composition and inhibiting the progress of curing while drying. In the single layer sheet or the resin sheet with the support, the resin composition can be used in an uncured state after simply drying the solvent, or can be used in a semi-cured state (stage B) as needed. Further, the thickness of the resin layer of the single layer sheet or the resin sheet with the support according to the present embodiment can be adjusted by the concentration and the coating thickness of the solution of the resin composition of the present embodiment, and not particularly limited, and the thickness is preferably, 0.1 to 500 μm in view of easily removing the solvent when drying.

### [Laminate]

The laminate of the present embodiment contains one or more selected from the group consisting of the prepreg and the resin sheet of the present embodiment. In the case of two or more of the prepregs and the resin sheets are laminated, the resin composition used for each prepreg and resin sheet can be the same or different. In the case of using both prepreg and resin sheet, the resin composition used for these can be the same or different. In the laminate of the present embodiment, the one or more selected from the group consisting of the prepreg and the resin sheet can be in a semi-cured state (stage B) or a completely cured state (stage C).

### [Metal Foil-Clad Laminate]

The metal foil-clad laminate of the present embodiment contains the laminate of the present embodiment and a metal foil disposed on one side or each of both sides of the laminate.

The metal foil-clad laminate can contain at least 1 sheet of the prepreg of the present embodiment and a metal foil laminated on one side or each of both sides of the prepreg.

The metal foil-clad laminate can contain at least 1 resin sheet of the present embodiment and a metal foil laminated on one side or each of both sides of the resin sheet.

In the metal foil-clad laminate of the present embodiment, the resin composition used for each prepreg and resin sheet can be the same or different. In the case of using both prepreg and resin sheet, the resin composition used for these can be the same or different. In the metal foil-clad laminate of the present embodiment, the one or more selected from the group consisting of the prepreg and the resin sheet can be in a semi-cured state or a completely cured state.

In the metal foil-clad laminate of the present embodiment, a metal foil is laminated on one or more selected from the group consisting of the prepreg of the present embodiment and the resin sheet of the present embodiment; however, it is preferable that a metal foil be laminated in such a way as to contact the surface of the one or more selected from the group consisting of the prepreg of the present embodiment and the resin sheet of the present embodiment. “The metal foil be laminated in such a way as to contact the surface of the one or more selected from the group consisting of the prepreg and the resin sheet” means that a layer such as an adhesive layer is not included between the prepreg or resin sheet and the metal foil, but that the prepreg or resin sheet directly contacts the metal foil. Due to this, the peel strength of the metal foil of the metal foil-clad laminate increases, and the insulation reliability of a printed wiring board tends to be enhanced.

The metal foil-clad laminate of the present embodiment can have one or more laminated prepregs and/or resin sheets of the present embodiment and the metal foil(s) disposed on one side or both sides of the prepregs and/or resin sheets. Examples of the production method of the metal foil-clad laminate of the present embodiment include a method in which one or more laminated prepregs and/or resin sheets of the present embodiment, and the metal foil(s) disposed on one side or both sides thereof are laminated. Examples of the formation method include a method typically used when forming a laminate and a multilayer board for a printed wiring board, and more specific examples include a method of laminating using a multistage press machine, a multistage vacuum press machine, a continuous molding machine, or an autoclave molding machine, at a temperature of about 180 to 350° C., for heating time of about 100 to 300 minutes, and a surface pressure of about 20 to 100 kgf/cm².

Further, the prepreg and/or the resin sheet of the present embodiment is laminated in combination with a separately manufactured wiring board for an inner layer to form a multilayer board. In the production method of the multilayer board, for example, copper foils having a thickness of about 35 μm are disposed on both sides of one or more laminated prepregs and/or resin sheets of the present embodiment, and laminated by the above formation method to prepare a copper foil-clad laminate. Then, an inner layer circuit is formed and subjected to blacking treatment to form an inner layer circuit board, and then the inner layer circuit boards and the prepregs and/or resin sheets of the present embodiment are alternately disposed one by one. Further, copper foils are disposed on the outermost layers to laminate under the above conditions, preferably under vacuum, whereby a multilayer board can be manufactured. The metal foil-clad laminate of the present embodiment can be suitably used as a printed wiring board.

### (Metal Foil)

The metal foil is not particularly limited, and examples include a gold foil, a silver foil, a copper foil, a tin foil, a nickel foil, and an aluminum foil. Of these, a copper foil is preferable. The copper foil is not particularly limited as long as it is generally used as a material for a printed wiring board, and examples include copper foils such as a rolled copper foil, and an electrolytic copper foil. Of these, an electrolytic copper foil is preferable, in view of copper foil peel strength and fine wiring formation. The thickness of a copper foil is not particularly limited and can be about 1.5 to 70 μm.

### [Printed Wiring Board]

The printed wiring board of the present embodiment has an insulation layer and a conductor layer disposed on one side or each of both sides of the insulation layer, wherein the insulation layer contains a cured product of the resin composition of the present embodiment. The insulation layer preferably contains at least one of a layer formed of the resin composition of the present embodiment (the layer containing the cured product) and a layer formed of the prepreg (the layer containing the cured product). Such a printed wiring board can be produced according to a usual method, and the production method thereof is not particularly limited. For example, the printed wiring board can be produced by using the metal foil-clad laminate described above. Hereinafter, an example of the production method of the printed wiring board is described.

First, the metal foil-clad laminate described above is provided. Next, the surface of the metal foil-clad laminate is subjected to etching treatment to form an inner layer circuit, thereby manufacturing an inner layer substrate. The surface treatment for increasing the adhesive strength is carried out, as needed, on the inner layer circuit surface of this inner layer substrate, then the required number of sheets of the above prepregs are laminated on the inner layer circuit surface, further a metal foil for an outer layer circuit is laminated on the outside thereof, thereby integrating by heating and pressing. Thus, the multilayer laminate is produced in which the base material and the insulation layer consisting of the cured product of the resin composition of the present embodiment are formed between the inner layer circuit and the metal foil for the outer layer circuit. Subsequently, this multilayer laminate is subjected to drilling for a through-hole or a via hole, then a plated metal film is formed on the wall surface of this hole for conducting the inner layer circuit and the metal foil for the outer layer circuit, further the metal foil for the outer layer circuit is subjected to etching treatment to form the outer layer circuit, whereby the printed wiring board is produced.

The printed wiring board obtained in the above production example has the structure in which the insulation layer and the conductor layer formed on the surface of this insulation layer, wherein the insulation layer contains the cured product of the resin composition according to the present embodiment. That is, the prepreg according to the present embodiment (containing the base material and the cured product of the resin composition of the present embodiment penetrating or coating it) and the layer of the resin composition of the metal foil-clad laminate of the present embodiment (the layer containing the cured product of the resin composition of the present embodiment) are structured by the insulation layer containing the cured product of the resin composition of the present embodiment.

### [Semiconductor Device]

The semiconductor device can be produced by mounting a semiconductor tip at a conductive point on the printed wiring board of the present embodiment. The conductive point herein refers to the point at which an electrical signal is transmitted in the multilayer printed wiring board, and such a place can be either on the surface or in an embedded point. Further, the semiconductor tip is not particularly limited as long as it is an electrical circuit element made of a semiconductor as a material.

The method for mounting a semiconductor tip when producing the semiconductor device is not particularly limited as long as the semiconductor tip effectively functions, and specifically examples include wire-bonding mounting method, flip-chip mounting method, bumpless build-up layer (BBUL) mounting method, anisotropic conductive film (ACE) mounting method, and non-conductive film (NCF) mounting method.

### EXAMPLES

Hereinafter, the present embodiment will be more specifically described by way of examples and comparative examples. The present embodiment is not limited at all by the following examples.

### [Measurement Method of Median Particle Size]

The median particle sizes (D50) of the surface-coated titanium oxide and the filler (spherical fused silica) were calculated by measuring a particle size distribution by the laser diffraction-scattering method under the following measurement conditions using a laser diffraction-scattering type particle size distribution analyzer (Microtrac MT3300EXII (product name), MicrotracBEL Corp.).

### (Conditions for Measurement Using a Laser Diffraction-Scattering Type Particle Size Distribution Analyzer)

### (Surface-Coated Titanium Oxide)

Solvent: methyl ethyl ketone, solvent refractive index: 1.33, particle refractive index: 2.72, transmittance: 85±5%.

### (Filler)

Solvent: methyl ethyl ketone, solvent refractive index: 1.33, particle refractive index: 1.45 (spherical fused silica), transmittance: 85±5%.

### [Synthesis Example 1] Synthesis of Naphthol Aralkyl-Type Cyanate Ester Compound (SN495V-CN)

300 g of a naphthol aralkyl-type phenolic resin (in terms of OH group 1.28 mol) (SN495V (product name), OH group (hydroxy group) equivalent: 236 g/eq., new Nippon Steel Chemical Co., Ltd.) and 194.6 g of triethylamine (1.92 mol) (1.5 mol based on 1 mol of hydroxy group) were dissolved in 1800 g of dichloromethane, and the resultant was designated as Solution 1. 125.9 g of cyanogen chloride (2.05 mol) (1.6 mol based on 1 mol of hydroxy group), 293.8 g of dichloromethane, 194.5 g of 36% hydrochloric acid (1.92 mol) (1.5 mol based on 1 mol of hydroxy group), and 1205.9 g of water were stirred while maintaining the solution temperature at −2 to −0.5° C., into which Solution 1 was pored over a period of 30 minutes. After completion of pouring Solution 1, the resulting solution was stirred at the same temperature for 30 minutes, and a solution in which 65 g of triethylamine (0.64 mol) (0.5 mol based on 1 mol of hydroxy group) was dissolved in 65 g of dichloromethane (Solution 2) was poured thereinto over a period of 10 minutes. After completion of pouring Solution 2, the resultant was stirred for 30 minutes at the same temperature, and the reaction was completed. Subsequently, the reaction liquid was allowed to stand for separating the organic phase and the aqueous phase, and the obtained organic phase was washed 5 times with 1300 g of water. An electrical conductivity of waste water at the 5th water-washing was 5 μS/cm, thereby confirming that ionic compounds removable by washing with water were sufficiently removed. The organic phase after washed with water was concentrated under reduced pressure and finally concentrated to dryness at 90° C. for 1 hour, thereby obtaining 331 g of the intended naphthol aralkyl-type cyanate ester compound (SN495V-CN, cyanate ester group equivalent: 261 g/eq., R³ in the above formula (1) are all hydrogen atoms, and n3 is an integer of 1 to 10) (orange color viscous substance). An infrared absorption spectrum of the obtained SN495V-CN showed the absorption at 2250 cm⁻¹ (cyanate ester group), and did not show the absorption of hydroxy group.

### Example 1

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., minimum melt viscosity: 1,000 Pa·s), 80 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 26:74 (surface-coated titanium oxide:filler) in a volume ratio.

The obtained resin varnish was allowed to penetrate and coat an E glass cloth (1031NT 5640 (product name), Arisawa Mfg. Co., Ltd.) having a thickness of 0.094 mm and heated to dry at 130° C. for 3 minutes, thereby obtaining a prepreg having a thickness of 0.1 mm. Next, electrolytic copper foils (3EC-M3-VLP (product name), MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (a double-sided copper-clad laminated sheet) having a thickness of 0.124 mm. Physical properties of the obtained resin varnish, prepreg, and metal foil-clad laminate were measured in accordance with the evaluation methods, and the measurement results were shown in Table 1.

### Example 2

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., minimum melt viscosity: 1,000 Pa·s), 80 parts by mass of surface-coated titanium oxide (shape: amorphous, crystal structure: rutile-type, titanium oxide obtained by surface treating titanium dioxide with alumina and a silicone oil (content of alumina: 1.0 mass %, and content of silicone oil: 1.0 mass %), and having the laminated structure of a layer containing alumina, and a layer having the siloxane structure (derived from the silicone oil) in this order from the surface of titanium dioxide (core particle), the titanium oxide content: 98 mass %, median particle size (D50): 0.20 μm, R-11P (product name), SAKAI CHEMICAL INDUSTRY CO., LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 26:74 (surface-coated titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 1.

### Example 3

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., minimum melt viscosity: 1,000 Pa·s), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 43:57 (surface-coated titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 1.

### Example 4

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of polyphenylmethane maleimide (BMI-2300 (product name), Daiwa Kasei Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., minimum melt viscosity: 1,000 Pa·s), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 43:57 (surface-coated titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 1.

### Example 5

A resin varnish was obtained by mixing 8 parts by mass of a bisphenol A-type cyanate ester compound (Primaset (registered trademark) BADCy (product name), Lonza), 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., minimum melt viscosity: 1,000 Pa·s), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 43:57 (surface-coated titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 1.

### Example 6

A resin varnish was obtained by mixing 36 parts by mass of the naphthol aralkyl-type cyanate ester compound (SN495V-CN, cyanate ester group equivalent: 261 g/eq.) obtained in Synthesis Example 1, 14 parts by mass of 2,2-bis(4-(4-maleimidephenoxy)-phenyl)propane (BMI-80 (product name), K.I Chemical Industry Co., Ltd.), 14 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., minimum melt viscosity: 1,000 Pa·s), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 43:57 (surface-coated titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 1.

### Example 7

A resin varnish was obtained by mixing 36 parts by mass of the naphthol aralkyl-type cyanate ester compound (SN495V-CN, cyanate ester group equivalent: 261 g/eq.) obtained in Synthesis Example 1, 64 parts by mass of a biphenyl aralkyl-type maleimide compound (MIR-3000-70MT (product name), Nippon Kayaku Co., Ltd.), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 43:57 (surface-coated titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 1.

### Example 8

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., the minimum melt viscosity: 1,000 Pa·s), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.).

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 1.

### Example 9

A resin varnish was obtained by mixing 64 parts by mass of the naphthol aralkyl-type cyanate ester compound (SN495V-CN, cyanate ester group equivalent: 261 g/eq.) obtained in Synthesis Example 1, 36 parts by mass of a biphenyl aralkyl-type maleimide compound (MIR-3000-70MT (product name), Nippon Kayaku Co., Ltd.), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 43:57 (surface-coated titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 1.

### Example 10

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., minimum melt viscosity: 1,000 Pa·s), 80 parts by mass of surface-coated titanium oxide (shape: amorphous, crystal structure: rutile-type, titanium oxide obtained by surface treating titanium dioxide with alumina and organosilane (content of alumina: 0.7 mass %, and content of organosilane: 1.3 mass %), and having the laminated structure of a layer containing alumina, and a layer having the siloxane structure (derived from the organosilane) in this order from the surface of titanium dioxide (core particle), the titanium oxide content: 98 mass %, median particle size (D50): 0.40 μm, R-22L (product name), SAKAI CHEMICAL INDUSTRY CO., LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 26:74 (surface-coated titanium oxide:filler) in a volume ratio.

The obtained resin varnish was allowed to penetrate and coat an E glass cloth (1031NT 5640 (product name), Arisawa Mfg. Co., Ltd.) having a thickness of 0.094 mm and heated to dry at 130° C. for 3 minutes, thereby obtaining a prepreg having a thickness of 0.1 mm. Next, electrolytic copper foils (3EC-M3-VLP (product name), MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (a double-sided copper-clad laminated sheet) having a thickness of 0.124 mm. Physical properties of the obtained resin varnish, prepreg, and metal foil-clad laminate were measured in accordance with the evaluation methods, and the measurement results were shown in Table 1.

### Comparative Example 1

A resin varnish was obtained by mixing 54 parts by mass of the naphthol aralkyl-type cyanate ester compound (SN495V-CN, cyanate ester group equivalent: 261 g/eq.) obtained in Synthesis Example 1, 5 parts by mass of 2,2-bis(4-(4-maleimidephenoxy)-phenyl)propane (BMI-80 (product name), K.I Chemical Industry Co., Ltd.), 5 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., minimum melt viscosity: 1,000 Pa·s), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 43:57 (surface-coated titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 2.

### Comparative Example 2

A resin varnish was obtained by mixing 64 parts by mass of the naphthol aralkyl-type cyanate ester compound (SN495V-CN, cyanate ester group equivalent: 261 g/eq.) obtained in Synthesis Example 1, 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., the minimum melt viscosity: 1,000 Pa·s), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 43:57 (surface-coated titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 2.

### Comparative Example 3

A resin varnish was obtained by mixing 32 parts by mass of 2,2-bis(4-(4-maleimidephenoxy)-phenyl)propane (BMI-80 (product name), K.I Chemical Industry Co., Ltd.), 32 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., minimum melt viscosity: 1,000 Pa·s), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 43:57 (surface-coated titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 2.

### Comparative Example 4

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC Corporation), 24 parts by mass of a modified polyphenylene ether compound (OPE-2St 1200 (product name), MITSUBISHI GAS CHEMICAL COMPANY, INC., number average molecular weight: 1187, vinyl group equivalent: 590 g/eq., the minimum melt viscosity: 1,000 Pa·s), 175 parts by mass of titanium oxide (shape: amorphous, crystal structure: rutile-type, the titanium oxide content: 100 mass %, median particle size (D50): 0.21 μm, R-310 (product name), SAKAI CHEMICAL INDUSTRY CO., LTD.), 120 parts by mass of spherical fused silica (SC4500-SQ (product name), median particle size (D50): 1.1 μm, Admatechs Company Limited), 4 parts by mass of a silane coupling agent (KBM-403 (product name), Shin-Etsu Chemical Co., Ltd.), 2 parts by mass of a wetting and dispersing agent (DISPERBYK (registered trademark)-161 (product name), BYK Japan KK), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.). The blending ratio (content ratio) of the surface-coated titanium oxide to the filler (SC4500-SQ (product name)) in the resin varnish was 43:57 (titanium oxide:filler) in a volume ratio.

Using the obtained resin varnish, a prepreg having a thickness of 0.1 mm, and a metal foil-clad laminate (a double-sided copper-clad laminated sheet) having a thickness of 0.124 mm were manufactured in the same manner as in Example 1. Physical properties of the obtained resin varnish, prepreg, and metal foil-clad laminate were measured in accordance with the evaluation methods, and the measurement results were shown in Table 2.

### Comparative Example 5

A resin varnish was obtained by mixing 12 parts by mass of the naphthol aralkyl-type cyanate ester compound (SN495V-CN, cyanate ester group equivalent: 261 g/eq.) obtained in Synthesis Example 1, 44 parts by mass of 2,2-bis(4-(4-maleimidephenoxy)-phenyl)propane (BMI-80 (product name), K.I Chemical Industry Co., Ltd.), 44 parts by mass of a biphenyl aralkyl-type maleimide compound (MIR-3000-70MT (product name), Nippon Kayaku Co., Ltd.), 175 parts by mass of surface-coated titanium oxide (shape: amorphous, crystal structure: rutile-type, titanium oxide obtained by surface treating titanium dioxide with silica, alumina, and dimethyl silicone (the total content of silica, alumina, and dimethyl silicone: 3 mass %), and having the laminated structure of an inorganic oxide layer, and a layer having the siloxane structure (derived from the dimethyl silicone) in this order from the surface of titanium dioxide (core particle), the titanium oxide content: 97 mass %, median particle size (D50): 0.21 μm, CR-63 (product name), ISHIHARA SANGYO KAISHA, LTD.), 4 parts by mass of a wetting and dispersing agent (BYK (registered trademark)-W903 (product name), BYK Japan KK), and 0.1 parts by mass of 2,4,5-triphenyl imidazole (Tokyo Chemical Industry Co., Ltd.).

Using the obtained resin varnish, a prepreg having a thickness of 0.1 mm, and a metal foil-clad laminate (a double-sided copper-clad laminated sheet) were manufactured in the same manner as in Example 1. Physical properties of the obtained resin varnish, prepreg, and metal foil-clad laminate were measured in accordance with the evaluation methods, and the measurement results were shown in Table 1.

### [Evaluation Methods]

### (1) Evaluation of the Resin Varnishes (Measurement of Resin Curing Time)

The resin varnishes obtained in Examples and Comparative Examples were injected into a tester (Auto Gel Time Tester MADOKA (product name), Matsuo Sangyo Co., Ltd.) using a micropipette and the time (second) taken to cure the resin was measured under the following measurement conditions.

### (Measurement Conditions)

Heated plate temperature: 170° C., torque judgment value: 15%, rotation speed: 190 rpm, revolution speed: 60 rpm, gap value: 0.3 mm, average point: 50, amount injected: 500 μL.

### (2) Evaluation of the Metal Foil-Clad Laminates

### (Thickness of Unclad Laminate)

All the copper foils on both sides of the metal foil-clad laminates obtained in Examples and Comparative Examples were etched, thereby obtaining unclad laminates from which all the copper foils on both sides were removed. The thickness of this unclad laminates was measured using a measuring device (laminate thickness gauge (product name), ONO SOKKI CO., LTD.). In Comparative Example 5, the curing time of the resin varnish was extended, and thus a good coatability and appearance were not obtained.

### (Glass Transition Temperature (Tg))

All the copper foils on both sides of the metal foil-clad laminates obtained in Examples and Comparative Examples were etched, thereby obtaining unclad laminates from which all the copper foils on both sides were removed. The unclad laminate was cut (downsized) to a size of 40 mm×4.5 mm, thereby obtaining a sample for measurement. On this sample for measurement, the glass transition temperature (Tg, ° C.) was measured by the DMA method in accordance with JIS C6481 using a dynamic mechanical analyzer (Q800 (product name), TA Instruments)

### (Coefficient of Thermal Expansion (CTE))

All the copper foils on both sides of the metal foil-clad laminates obtained in Examples and Comparative Examples were etched, thereby obtaining unclad laminates from which all the copper foils on both sides were removed. The unclad laminate was cut (downsized) to a size of 40 mm×4.5 mm, thereby obtaining a sample for measurement. On this sample for measurement, the coefficient of thermal expansion (CTE, ppm/° C.) in a cross direction from 60° C. to 120° C. was measured in accordance with JIS C6481 using a thermomechanical analyzer (Q400 (product name), TA Instruments) in a rate of temperature increase of 10° C. per minute from 40° C. to 340° C. The measurement direction was the machine direction (Warp) of glass cloth of the laminate.

### (Relative Permittivity (Dk) and Dissipation Factor (Df))

All the copper foils on both sides of the metal foil-clad laminates obtained in Examples and Comparative Examples were etched, thereby obtaining unclad laminates from which all the copper foils on both sides were removed. The unclad laminate was cut (downsized) to a size of 1 mm×65 mm, thereby obtaining a sample for measurement.

On this sample for measurement, the relative permittivity (Dk) and dissipation factor (Df) at 10 GHz were each measured using a network analyzer (Agilent 8722ES (product name), Agilent Technologies, Inc.). The measurement of the relative permittivity (Dk) and dissipation factor (Df) was carried out under the environment at a temperature of 23° C.±1° C., and a humidity of 50% RH (relative humidity)±5% RH.

### (Moisture Absorption and Heat Resistance Evaluation)

Ultrathin copper foils with carrier (MT18FL (product name), MITSUI MINING & SMELTING CO., LTD., thickness: 1.5 μm) were disposed on the upper and lower sides of the prepregs obtained in Examples and Comparative Examples, and laminated by vacuum pressing at a surface pressure of 30 kgf/cm² and a temperature of 220° C. for 120 minutes, thereby manufacturing a metal foil-clad laminate (a double-sided copper-clad laminated sheet). Next, all the copper foils on both sides were etched, thereby obtaining unclad laminates from which all the copper foils on both sides were removed. Prepregs having a thickness of 0.06 mm (GHPL-970LF (LD) (product name), MITSUBISHI GAS CHEMICAL COMPANY, INC.) were disposed on the upper and lower sides of this unclad laminate, and electrolytic copper foils (3EC-M3-VLP (product name), MITSUI MINING & SMELTING CO., LTD.) having a thickness of 12 μm were further disposed on the upper and lower sides thereof. Laminating was carried out by vacuum pressing at a surface pressure of 30 kgf/cm² and a temperature of 220° C. for 120 minutes, thereby manufacturing a metal foil-clad laminate (a double-sided copper-clad laminated sheet) having a thickness of 0.22 mm (in Comparative Example 5, the metal foil-clad laminate had a thickness of less than 0.22 mm). The obtained laminate was cut (downsized) to a size of 50 mm×50 mm. The copper foils on one side were all etched and removed, and on the other side the copper foil on a half of the surface was etched and removed, thereby manufacturing a sample for measurement.

The obtained sample for measurement was dipped for 1 hour in pure water boiled to 100° C., and then dipped for 60 seconds in a solder bath at 260° C. or 280° C. to visually observe the presence or absence of abnormality in appearance changes.

Additionally, the sample for measurement obtained in the same manner as above was dipped for 2 hours, instead of 1 hour, in pure water boiled to 100° C., and then dipped for 60 seconds in a solder bath at 260° C. or 280° C. to visually observe the presence or absence of abnormality in appearance changes.

Further, the sample for measurement obtained in the same manner as above was treated for 0.5 hours, using a pressure cooker test chamber (PC-3 type (product name), HIRAYAMA Manufacturing Corporation), at 121° C. and in the presence of saturated water vapor at 2 atmospheric pressure, and then dipped for 60 seconds in a solder bath at 260° C. or 280° C. to visually observe the presence or absence of abnormality in appearance changes.

For each of the measurement, 4 samples were tested, and the case where all 4 samples had no abnormality was rated as “A”, and the case where even 1 out of 4 samples had appearance abnormality was rated as “C”. In the case where, for example, swells were caused on the copper foil surface or the back of the sample after dipping, it was determined that the sample has appearance abnormality. In Tables 1 and 2, “Boiled 1.0 h” and “Boiled 2.0 h” show the results of the samples immersed in pure water at 100° C. for 1 hour and 2 hours, respectively. The “PCT 0.5 h” shows the results after the 0.5 hour-treatment using a pressure cooker test chamber.

TABLE 1

| | | | | Exam- | Exam- | Exam- | Exam- | Exam- | Exam- | Exam- | Exam- | Exam- | Exam- |
|---|---|---|---|---|---|---|---|---|---|---|---|---|---|
| | | | | ple 1 | ple 2 | ple 3 | ple 4 | ple 5 | ple 6 | ple 7 | ple 8 | ple 9 | ple 10 |
| Physical | Resin varnish-curing time [sec] | | | 417 | 419 | 366 | 253 | 238 | 312 | 365 | 389 | 302 | 401 |
| properties | Unclad laminate thickness [μm] | | | 100 | 100 | 100 | 100 | 100 | 100 | 100 | 100 | 100 | 100 |
| | Glass transition temperature | | | 291 | 292 | 269 | 276 | 252 | 234 | 298 | 271 | 265 | 294 |
| | [Tg, ° C.] | | | | | | | | | | | | |
| | Coefficient of thermal expansion | | | 8.9 | 8.7 | 9.8 | 9.4 | 9.9 | 10.1 | 9.0 | 10.5 | 9.3 | 8.5 |
| | [CTE, ppm/° C.] | | | | | | | | | | | | |
| | Relative permittivity [Dk, 10 GHz] | | | 5.1 | 5.0 | 5.9 | 6.1 | 6.1 | 6.0 | 6.1 | 7.1 | 5.9 | 4.9 |
| | Dissipation factor [Df, 10 GHz] | | | 0.010 | 0.009 | 0.010 | 0.012 | 0.010 | 0.009 | 0.009 | 0.012 | 0.009 | 0.010 |
| | Moisture | Boiled | 260° C. | A | A | A | A | A | A | A | A | A | A |
| | absorption | 1.0 h | 60 sec-dip | | | | | | | | | | |
| | and heat | | 280° C. | A | A | A | A | A | A | A | A | A | A |
| | resistance | | 60 sec-dip | | | | | | | | | | |
| | | Boiled | 260° C. | A | A | A | A | A | A | A | A | A | A |
| | | 2.0 h | 60 sec-dip | | | | | | | | | | |
| | | | 280° C. | A | A | A | A | A | A | A | A | A | A |
| | | | 60 sec-dip | | | | | | | | | | |
| | | PCT | 260° C. | A | A | A | A | A | A | A | A | A | A |
| | | 0.5 h | 60 sec-dip | | | | | | | | | | |
| | | | 280° C. | A | A | A | A | A | A | A | A | A | A |
| | | | 60 sec-dip | | | | | | | | | | |

TABLE 2

| | | | | Comparative | Comparative | Comparative | Comparative | Comparative |
|---|---|---|---|---|---|---|---|---|
| | | | | Example 1 | Example 2 | Example 3 | Example 4 | Example 5 |
| Physical | Resin varnish-curing time [sec] | | | 356 | 432 | 315 | 352 | >999 |
| properties | Unclad laminate thickness [μm] | | | 100 | 100 | 100 | 100 | 90 |
| | Glass transition temperature [Tg, ° C.] | | | 226 | 217 | 287 | 294 | 303 |
| | Coefficient of thermal expansion | | | 10.7 | 9.9 | 10.3 | 9.1 | 9.0 |
| | [CTE, ppm/° C.] | | | | | | | |
| | Relative permittivity [Dk, 10 GHz] | | | 6.0 | 6.1 | 6.1 | 5.6 | 6.2 |
| | Dissipation factor [Df, 10 GHz] | | | 0.009 | 0.009 | 0.012 | 0.010 | 0.009 |
| | Moisture | Boiled | 260° C. 60 sec-dip | A | A | A | A | A |
| | absorption | 1.0 h | 280° C. 60 sec-dip | A | A | A | A | A |
| | and heat | Boiled | 260° C. 60 sec-dip | C | A | A | A | A |
| | resistance | 2.0 h | 280° C. 60 sec-dip | C | A | A | A | A |
| | | PCT | 260° C. 60 sec-dip | C | A | A | C | A |
| | | 0.5 h | 280° C. 60 sec-dip | C | C | C | C | A |

The present application claims priority to the Japanese Patent Application (Patent Application 2021-090391) filed in Japan Patent Office on May 28, 2021, and priority to the Japanese Patent Application (Patent Application 2022-046580) filed in Japan Patent Office on Mar. 23, 2022, and the contents of which are incorporated herein by reference.

### INDUSTRIAL APPLICABILITY

The resin composition of the present invention has a high permittivity and a low dissipation factor, and has excellent moisture absorption and heat resistance, a high glass transition temperature, a low coefficient of thermal expansion, and also a good coatability and appearance. For this reason, the resin composition of the present invention, for example, can be suitably used as a raw material for a cured product, a prepreg, a film-like underfill material, a resin sheet, a laminate, a build-up material, a non-conductive film, a metal foil-clad laminate, a printed wiring board, and a fiber-reinforced composite material, or for producing a semiconductor device.

1. A resin composition, comprising:
(A) a cyanate ester compound,
(B) a maleimide compound, and
(C) a surface-coated titanium oxide,
wherein a content of the cyanate ester compound (A) is 1 to 65 parts by mass, based on 100 parts by mass of a total resin solid content in the resin composition, and
a content of the maleimide compound (B) is 15 to 85 parts by mass, based on 100 parts by mass of the total resin solid content in the resin composition.

2. The resin composition according to claim 1, wherein the cyanate ester compound (A) comprises one or more selected from the group consisting of phenol novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallyl bisphenol A-type cyanate ester compounds, bisphenol E-type cyanate ester compounds, bisphenol F-type cyanate ester compounds, and biphenyl aralkyl-type cyanate ester compounds, and prepolymers or polymers of these cyanate ester compounds.

3. The resin composition according to claim 1, wherein the maleimide compound (B) comprises one or more selected from the group consisting of bis(4-maleimidephenyl)methane, 2,2-bis(4-(4-maleimidephenoxy)-phenyl)propane, bis(3-ethyl-5-methyl-4-maleimidephenyl)methane, maleimide compounds represented by the following formula (2), and maleimide compounds represented by the following formula (3): 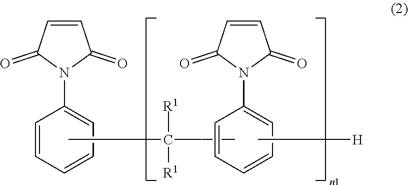
wherein R¹ each independently represents a hydrogen atom or a methyl group, and n1 is an integer of 1 to 10, 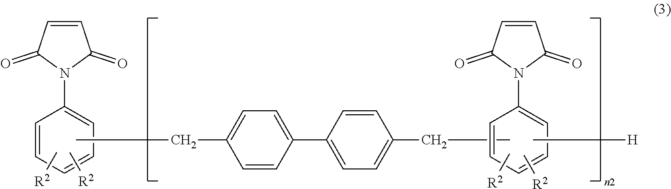
wherein R² each independently represents a hydrogen atom, an alkyl group having 1 to 5 carbon atoms, or a phenyl group, n2 is an average value and represents 1<n2≤5.

4. The resin composition according to claim 1, further comprising one or more thermosetting resins or compounds selected from the group consisting of epoxy compounds, phenolic compounds, modified polyphenylene ether compounds, alkenyl-substituted nadiimide compounds, oxetane resins, benzoxazine compounds, and compounds having a polymerizable unsaturated group.

5. The resin composition according to claim 1, wherein the surface-coated titanium oxide (C) has an organic layer and/or an inorganic oxide layer on the surface of a titanium oxide particle.

6. The resin composition according to claim 5, wherein a total amount of the organic layer and the inorganic oxide layer is 0.1 to 10 mass %, based on 100 mass % of the surface-coated titanium oxide (C).

7. The resin composition according to claim 5, wherein the inorganic oxide layer is one or more selected from the group consisting of a layer comprising silica, a layer comprising zirconia, and a layer comprising alumina.

8. The resin composition according to claim 7, wherein the surface-coated titanium oxide (C) further has the organic layer on the surface of the inorganic oxide layer.

9. The resin composition according to claim 1, wherein a content of the surface-coated titanium oxide (C) is 50 to 500 parts by mass, based on 100 parts by mass of a total resin solid content in the resin composition.

10. The resin composition according to claim 1, further comprising a filler different from the surface-coated titanium oxide (C).

11. The resin composition according to claim 10, wherein the filler comprises one or more selected from the group consisting of silica, alumina, barium titanate, strontium titanate, calcium titanate, aluminum nitride, boron nitride, boehmite, aluminum hydroxide, zinc molybdate, silicone rubber powder, and silicone composite powder.

12. The resin composition according to claim 10, wherein a content of the filler is 50 to 300 parts by mass, based on 100 parts by mass of a total resin solid content in the resin composition.

13. The resin composition according to claim 4, wherein the epoxy compound comprises one or more selected from the group consisting of biphenyl aralkyl-type epoxy resins, naphthalene-type epoxy resins, and naphthylene ether-type epoxy resins.

14. The resin composition according to claim 1, for use in a printed wiring board.

15. A prepreg, comprising:
abase material, and
the resin composition according to am claim 1 penetrating or coating the base material.

16. A resin sheet comprising the resin composition according to claim 1.

17. A laminate comprising the prepreg according to claim 15.

18. A metal foil-clad laminate, comprising:
the laminate according to claim 17, and
a metal foil disposed on one side or each of both sides of the laminate.

19. A printed wiring board, comprising:
an insulation layer, and
a conductor layer disposed on one side or each of both sides of the insulation layer,
wherein the insulation layer comprises a cured product of the resin composition according to claim 1.

20. A laminate comprising the resin sheet according to claim 16.
